(19) United States
(12) Patent Application Publication
(10) Pub. No.: US 2008/0129192 A1
(43) Pub. Date: Jun. 5, 2008

(54) ORGANIC LIGHT EMITTING DEVICE

(75) Inventors: Taiki Watanabe, Akishima-shi (JP); Kazunori Ueno, Ebina-shi (JP); Koichi Suzuki, Yokohama-shi (JP); Akira Tsuboyama, Machida-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/942,835

(22) Filed: Nov. 20, 2007

(30) Foreign Application Priority Data
Dec. 1, 2006 (JP) 2006-326054

(51) Int. Cl. H01L 27/32

(52) U.S. Cl. 313/504

(57) ABSTRACT

The present invention provides an organic light emitting device exhibiting optical output with high light emitting efficiency and high luminance at low applied voltages. The present invention provides an organic light emitting device including: a pair of electrodes formed of an anode and a cathode, at least one of which is transparent or semitransparent; and an organic layer interposed between the pair of electrodes and containing an organic compound, in which the organic layer containing the organic compound includes one or more organic radical compounds. The organic layer containing the organic radical compound is a hole injecting layer, a hole transporting layer, an electron injecting layer, an electron transporting layer, or a light emitting layer.

### BACKGROUND OF THE INVENTION

1. Field of the Invention

The present invention relates to an organic light emitting device, and more particularly, relates to a device which emits light when an electric field is applied to an organic layer containing an organic compound. Still more particularly, the present invention relates to an organic light emitting device with high light emitting efficiency containing an organic layer including an organic radical compound.

2. Description of the Related Art

The organic radical compound has been vigorously studied as an organic magnetic substance after the 1980s, and various organic radical compounds have been designed or synthesized as described in Macromolecules, 16, 7079 (1993), Macromolecules, 26, 4567 (1993), J. Org. Chem., 64, 7129 (1999), and Bull. Chem. Soc. Jpn., 64, 499 (1996).

In recent years, technological developments aiming at practical use of the organic radical compounds are performed, and the compounds draw attention especially in the battery field. For example, technological developments, described in Chem. Phys. Lett., 359, 351 (2002) and IEICE Trans. Electron., R85-C, 1256 (2002), in which the organic radical compound is used for a positive electrode or a cathode active substance of a secondary battery are performed. Among the technological developments, the development of, for example, secondary batteries (rechargeable lithium-ion batteries, etc.) utilizing high reactivity and a reversible oxidation-reduction reaction of the organic radical compound for discharging is advanced, which suggests a possibility of large volumetric batteries of high energy density having excellent stability.

However, the technological developments aiming at practical use of the organic radical compounds have not started or studies thereof have just started in fields other than the battery field, and thus there are no examples in which the organic radical compound is applied to the organic light emitting device. General organic radical compounds are of high reactivity and are extremely unstable to air, light, water, etc., which hinders the application thereof to the organic light emitting device.

### SUMMARY OF THE INVENTION

The present invention aims to provide an organic light emitting device which contains a layer including an organic radical compound and which exhibits optical output with high light emitting efficiency and high luminance at low applied voltages. The present invention also aims to provide an organic light emitting device which can be readily manufactured at relatively low cost.

To solve the above-mentioned problems, there is provided an organic light emitting device including: a pair of electrodes formed of an anode and a cathode, at least one of which is transparent or semitransparent; and an organic layer interposed between the pair of electrodes, in which the organic layer contains an organic radical compound represented by the following general formula (1) or (2):

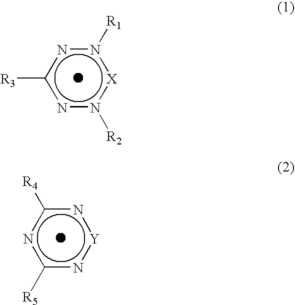

wherein, X represents a carbon atom, —(C═O)—, or —(C═S)—; Y represents an oxygen atom or a sulfur atom; and R₁ to R₅ each independently represent a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

Further, according to the present invention, there is provided an organic light emitting device including: a pair of electrodes formed of an anode and a cathode, at least one of which is transparent or semitransparent; and an organic layer interposed between the pair of electrodes, wherein the organic layer contains an organic radical compound represented by the following general formula (3):

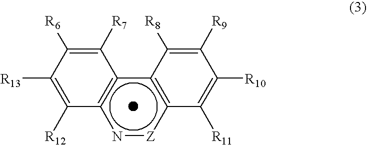

wherein Z represents an oxygen atom or a sulfur atom; and R₆ to R₁₃ each independently represent a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

Further, there is provided an organic light emitting device, including: a pair of electrodes formed of an anode and a cathode, at least one of which is transparent or semitransparent; and an organic layer interposed between the pair of electrodes, wherein the organic layer contains an organic radical compound represented by the following general formula (4):

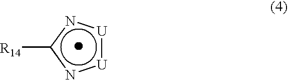

wherein U represents an oxygen atom or a sulfur atom; and R₁₄ represents a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

Still further, the organic light emitting device of the present invention includes in an organic layer, an organic radical compound having units each represented by any one of the general formulae (1) to (4) in which the units are directly bonded or bonded via a bivalent or trivalent aromatic ring, heterocyclic ring, or aromatic amine, and in addition an oligomer or polymer having units each represented by the general formulae (1) to (4) as a partial structure.

In the organic light emitting device of the present invention, the organic layer is formed using a mixture of an organic substance containing the organic radical compound and a solvent.

In the organic light emitting device of the present invention, when the organic layer is a hole injecting layer or a hole transporting layer, the organic light emitting device is imparted with high efficiency and excellent durability.

The present invention can provide an organic light emitting device containing a layer including an organic radical compound and exhibiting optical output with high light emitting efficiency and high luminance at low applied voltages. The present invention can also provide an organic light emitting device which can be readily manufactured at relatively low cost.

Further features of the present invention will become apparent from the following description of exemplary embodiments with reference to the attached drawings.

### BRIEF DESCRIPTION OF THE DRAWINGS

FIG. 1 is a cross sectional view illustrating an organic light emitting device according to one embodiment of the present invention.

FIG. 2 is a cross sectional view illustrating an organic light emitting device according to another embodiment of the present invention.

FIG. 3 is a cross sectional view illustrating an organic light emitting device according to still another embodiment of the present invention.

FIG. 4 is a cross sectional view illustrating an organic light emitting device according to yet another embodiment of the present invention.

FIG. 5 is a cross sectional view illustrating an organic light emitting device according to still yet another embodiment of the present invention.

FIG. 6 is a cross sectional view illustrating an organic light emitting device according to still yet another embodiment of the present invention.

FIG. 7 is a cross sectional view illustrating an organic light emitting device according to still yet another embodiment of the present invention.

FIG. 8 is a cross sectional view illustrating an organic light emitting device according to still yet another embodiment of the present invention.

### DESCRIPTION OF THE EMBODIMENTS

Hereinafter, the present invention will be described in detail.

The present invention provides an organic light emitting device including: a pair of electrodes formed of an anode and a cathode, at least one of which is transparent or semitransparent; and one or more organic layers each containing an organic compound, the one or more organic layers being interposed between the pair of electrodes, in which at least one layer of the organic layers each containing the organic compound includes at least one organic radical compound.

General radical compounds are of high reactivity, and unstable to environmental factors such as air, light, water, etc. In contrast, the organic radical compound used in the present invention forms and maintains a stable radical state or ionic state against the above-mentioned environmental factors. Moreover, the organic radical compound used in the present invention is not a radical compound which is confirmed by administration of a radical generator or under a specific environment (in an inert gas atmosphere, at low temperatures, or in the course of a chemical reaction) but is a stable radical compound which can be confirmed and identified at room temperature and in the atmosphere by an apparatus such as electron spin resonance (ESR). Further, the organic radical compound used in the present invention is also an organic radical compound which performs a reversible oxidation-reduction reaction (dope and dedope) in terms of electrochemical reaction. Hereinafter, the organic radical compound used in the present invention is also referred to as the organic radical compound of the present invention.

In more detail, the oxidation-reduction mechanism of the organic radical compound is represented by the following chemical formula.

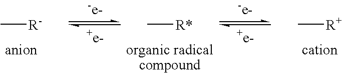

In the formula, e⁻ represents an electron and * represents a radical.

As shown above, the organic radical compound used in the present invention has two kinds of reaction cycles. To be specific, the two reaction cycles are: a reaction in which a stable radical is oxidized to form a cation, and the cation is reduced, thereby generating a stable radical again; and a reaction in which a stable radical is reduced to form an anion, and the anion is oxidized, thereby generating a stable radical again. The present invention uses the above-mentioned organic radical oxidation-reduction mechanism for the organic light emitting device.

Examples of the organic radical compounds include low molecular weight compounds, medium molecular weight compounds (an oligomer, a dendrimer, etc.), or high molecular weight compounds. The organic radical compound can be used for all the organic layers forming an organic light emitting device, and is suitably used for one or more organic layers selected from a hole injecting layer, a hole transporting layer, an electron injecting layer, an electron transporting layer, and a light emitting layer. Of those, the organic radical compound is preferably applied to the hole injecting layer or the hole transporting layer.

Molecules are designed in such a manner that thermal stability is high, e.g., glass transition temperature (Tg) is high. For example, materials with favorable membranous properties and thermal stability can be obtained by designing molecules to have a dendritic molecular shape of a starburst type or by polymerizing.

Moreover, the introduction of a steric hindrance group and/or a fluorine atom which has high electronegativity and is likely to cause electrostatic repulsion with adjacent molecules into a benzene-ring core, an anthryl group, and a substituent on an amino group can inhibit agglomeration of molecules and facilitate dissolution in various kinds of solvents. In addition to the above-mentioned requirements, the material of the present invention can also inhibit molecular vibration, improve thermal stability, give a heavy atom effect, etc., due to deuterium substitution effect.

Based on the above-mentioned concepts, the molecules of the organic radical compound are designed, the organic layer in the organic light emitting device is formed, and a high-efficient organic light emitting device is obtained, and thus the present invention has been accomplished.

Hereinafter, structural parts of the organic radical compound represented by general formulae (1) to (4) above are specifically described.

X shown in general formula (1) represents a carbon atom, —(C═O)—, or —(C═S)—, and Y shown in general formula (2) represents an oxygen atom or a sulfur atom. Z or U shown in general formula (3) or (4) represents an oxygen atom or a sulfur atom.

In general formulae (1) to (4), R₁ to R₁₄ each independently represent a hydrogen atom, a deuterium atom, halogen, an alkyl group (with a carbon number of preferably 1 to 12, and more preferably 1 to 6, e.g., a methyl group, a t-butyl group, a hexyl group, and a cyclohexyl group), an aralkyl group (e.g., monocyclic, polycyclic, or condensed-cyclic aralkyl groups with a carbon number of preferably 7 to 20 and more preferably 7 to 15 are mentioned, e.g., a benzyl group, and a phenethyl group, a naphthyl methyl group, and a naphthyl ethyl group), an alkenyl group (with a carbon number of preferably 2 to 12 and more preferably 2 to 6, and, for example, a propenyl group and the like are mentioned), an alkynyl group (with a carbon number of 2 to 12 and more preferably 2 to 6, e.g., an ethynyl group), a substituted or unsubstituted aromatic group (e.g., a benzene ring, a naphthalene ring, an anthracene ring, a phenanthrene ring, a fluorene ring, an acenaphthalene ring, an azulene ring, a heptacene ring, a heptaphene ring, an aceanthrylene ring, a pyrene ring, a perylene ring, a triphenylene ring, an pentacen ring, a coronene ring, a hexaphene ring, and a chrysene ring), or a substituted or unsubstituted heterocyclic group (e.g., a furan ring, a thiophene ring, a pyrrole ring, a pyrroline ring, a pyrrolidine ring, an oxazole ring, an isoxazol ring, a thiazole ring, an isothiazole ring, an imidazole ring, an imidazoline ring, an imidazolidine ring, a pyrazole ring, a pyrazolidine ring, a furazan ring, a pyrane ring, a pyrene ring, a pyridine ring, a piperidine ring, a pyridazine ring, a pyrimidine ring, a pyrazine ring, a piperazine ring, a moripholine ring, an indole ring, an indoline ring, an indazole ring, a chromene ring, a chroman ring, an isochroman ring, a quinoline ring, an isoquinoline ring, a cinnoline ring, a phthalazine ring, a quinazoline ring, a quinoxaline ring, a naphthyridine ring, a purine ring, a pteridine ring, a carbazole ring, an acridine ring, phenanthroline, phenoxazine, a thianthrene group, or a xanthene ring). It is a matter of course that R₁ to R₁₄ are not limited to the above, and that the rings may be directly bonded mutually or the rings may be bonded via a connecting group such as a carbon atom, a nitrogen atom, an oxygen atom, or a sulfur atom.

The units each represented by the general formulae (1) to (4) may be directly bonded or may be bonded through a bivalent or trivalent aromatic ring or heterocyclic ring. Usable as the aromatic ring or the heterocyclic ring are the same skeletons as those of the substituted or unsubstituted aromatic groups or the substituted or unsubstituted heterocyclic groups, and, in addition, bivalent or trivalent aromatic amines such as phenylamine, naphthylamine, biphenylamine, anthracenylamine, pyridyl amine, fluorenyl amine, methyl phenylamine, silyl phenylamine, hydroxyphenylamine, or the like. There is not limitation on a binding site for taking a bivalent or trivalent structure. The following are specific examples, but it is a matter of course that the present invention is not limited to the following.

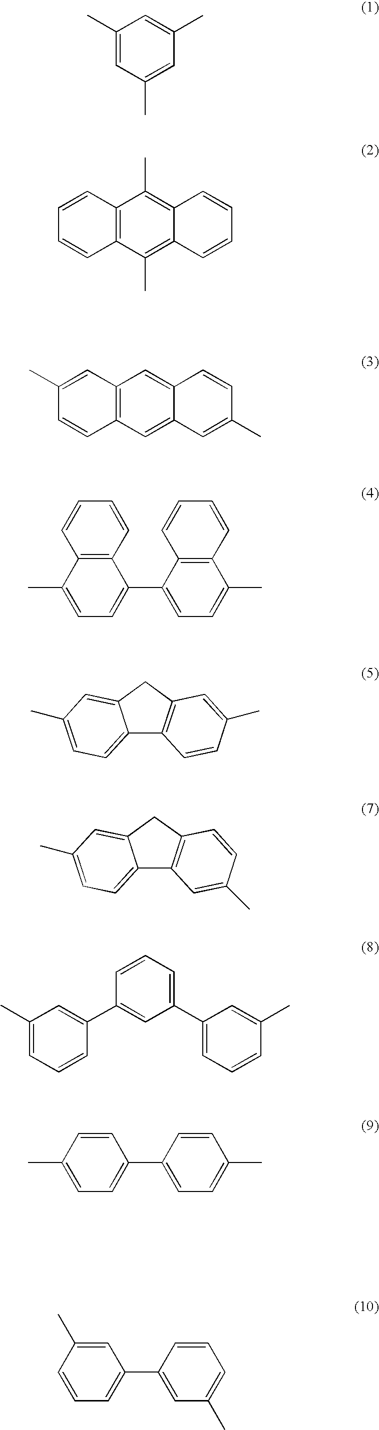

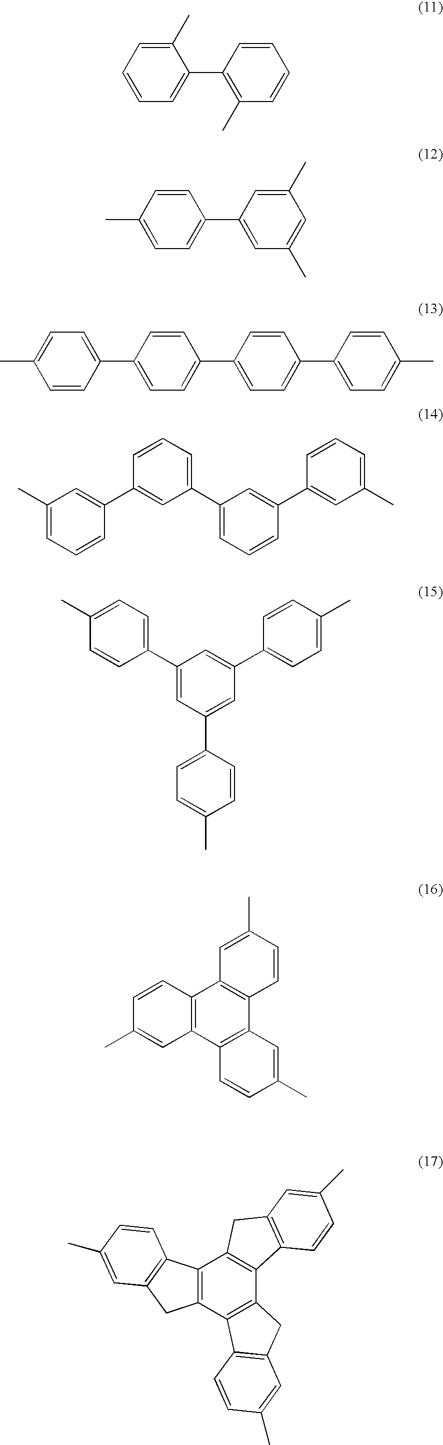

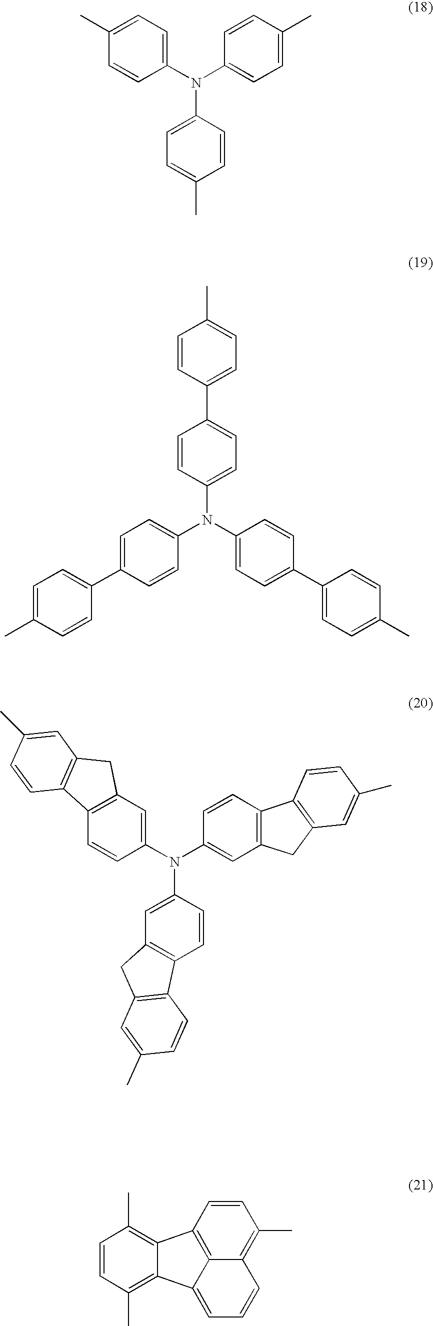

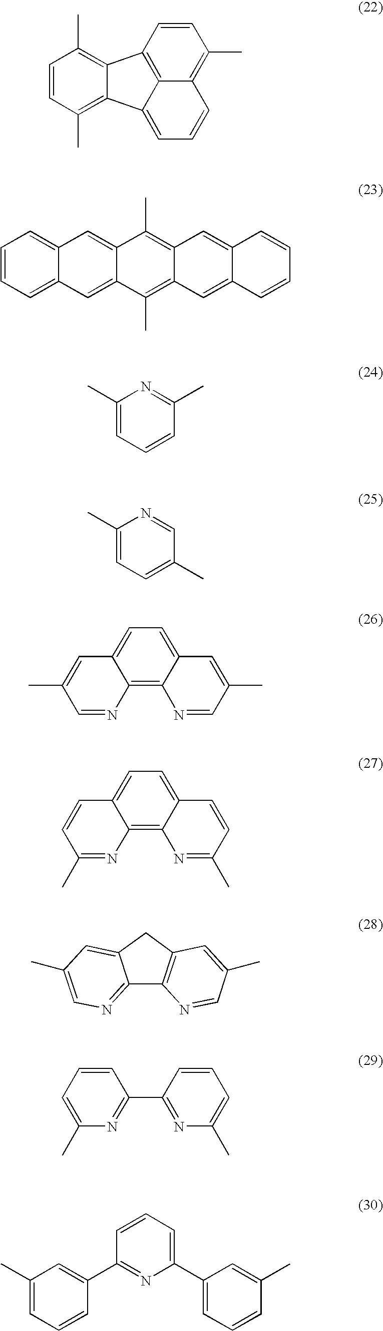

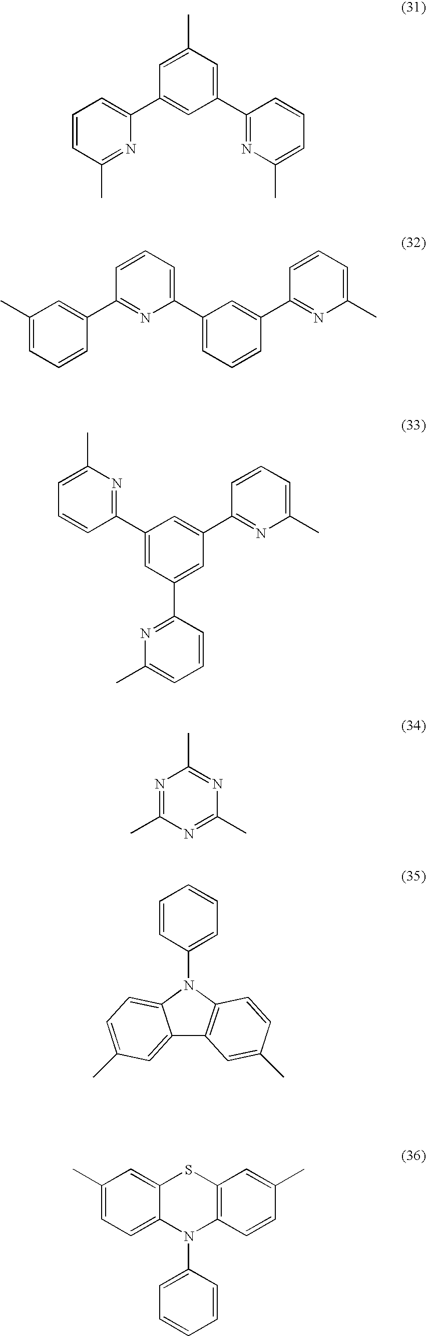

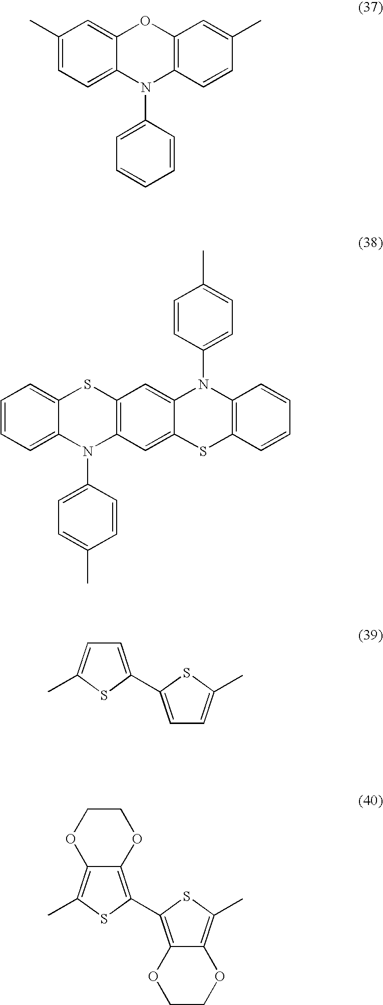

Further, the present invention can also contain, in the organic layer, oligomers or polymers containing the units each represented by general formulae (1) to (4) as a partial structure. In this case, the units each represented by the general formulae (1) to (4) can form oligomers or polymers through a connecting group. The connecting group is alkylene (one or more methylenes forming the alkylene may be replaced with —O—, —S—, —CO—, —CO—O—, —CO—NH—, —C═C—, —C≡C—, a substituted or unsubstituted bivalent aromatic ring, a substituted or unsubstituted bivalent heterocyclic ring, or a substituted or unsubstituted amine having two or more valences, and a hydrogen atom on the alkyl or a hydrogen atom on the replaced substituent may be replaced with a fluorine atom), aralkylene, alkenylene, alkynylene, or a substituted or unsubstituted polyvalent aromatic ring, polyvalent heterocyclic ring, or polyvalent amine.

The alkylene group may be a substituted alkylene group. Examples of the substituted alkylene group include methylene, d1-methylene, d3-methylene, ethylene, d5-ethylene, n-propylene, n-butylene, n-hexylene, n-octylene, isopropylene, d7-isopropylene, isobutylene, dimethylmethylene, isopentylene, neopentylene, difluoromethylene, perfluoroethylene, perfluoropropylene, perfluorobutylene, dichloromethylene, tetrachloroethyelene, 6-chlorohexylene, bromomethylene, 1,2-dibromoethyelene, iodomethylene, 2-bromoethylene, iodomethyelene, 2-iodoehtylene, hydroxymethylene, hydroxyethylene, cyclopropylene, cyclobutylene, cyclopentylmethylene, cyclohexylmethylene, cyclohexylethylene, and norbornylene groups. The d1-methylene group represents that one hydrogen atom on the methyl group is substituted with a duterium.

In addition, the aralkylene group include a substituted aralkylene group. Examples of the substituted aralkylene group include benzylene, 2-phenylethylene, 2-phenylisopropylene, 1-naphthylmethylene, 2-naphthylmethylene, 2-(1-naphtyl)ethylene, 2-(2-naphthyl)ethylene, 9-anthrylmethylene, 2-(9-anthryl)ethylene, 2-fluorobenzylene, 3-fluorobenzylene, 4-fluorobenzylene, 2-chlorobenzylene, 3-chlorobenzylene, 4-chlorobenzylene, 2-bromobenzylene, 3-bromobenzylene, and 4-bromobenzylene groups. The substituted aralkylene group is, of course, not limited thereto.

In addition, the alkenylene group include a substituted alkenylene group. Examples of the substituted alkenylene group include vinylene, ethenylene, propenylene, butenylene, pentenylene, 2-propenylene, Iso-propenylene, 2-butenylene, 3-butenylene, and styrylene groups. The substituted alkenylene group is, of course, not limited thereto.

Further, the alkynylene group of the present invention include a substituted alkynylene group. Example of the substituted alkynylene group include ethynylene, propynylene, butynylene, acetylenylene, phenylacetylenylene, and 1-propynylene groups. The substituted alkynylene group is, of course, not limited thereto.

In addition, examples of the substituted or unsubtituted divalent aromatic group or divalent heterocyclic ring include phenylene, naphthylene, biphnylene, anthracenedyl, pyridinedyl, thiopheneydilyl, fluorophenylene, chlorophenylene, methylphenylene, silylphenylene, hydroxyphenylene, aminophenylene, phenylenemethylenephenylene, phenyleneoxyphenylene, phenylenepropylidenephenylene, phenylene(hexafluoropropylidene)phenylene, piperidinylene, pyrrolidinylene, imidazolidinylene, pyrazolidinylene, piperazinylene, pyridinylene, pyridazinylene, pyrimidinylene, pyrazinylene, pyrazolylene, imidazolylene, pyrrolylene, pyrazolinylene, and triazinylene.

Further, examples of the substituted or unsubstituted polyamine having two or more valence include phenylamine, naphthylamine, biphenylamine, anthracenylamine, pyridylamine, fluorenylamine, methylphenylamine, silylphenylamine, and hydroxyphenylamine.

The following compounds are specifically mentioned as the organic radical compounds of the present invention, and it is a matter of course that the present invention is not limited to the following.

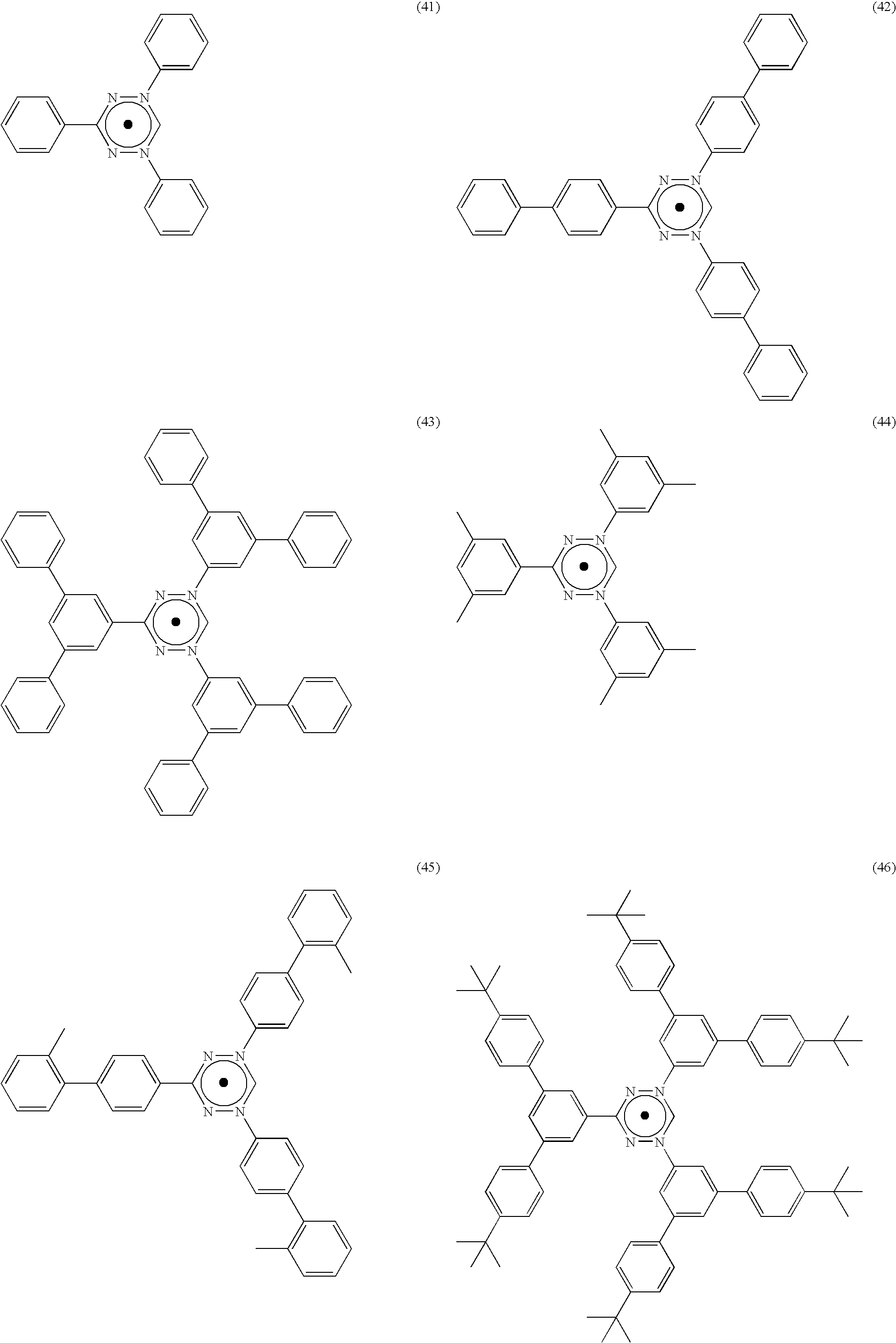

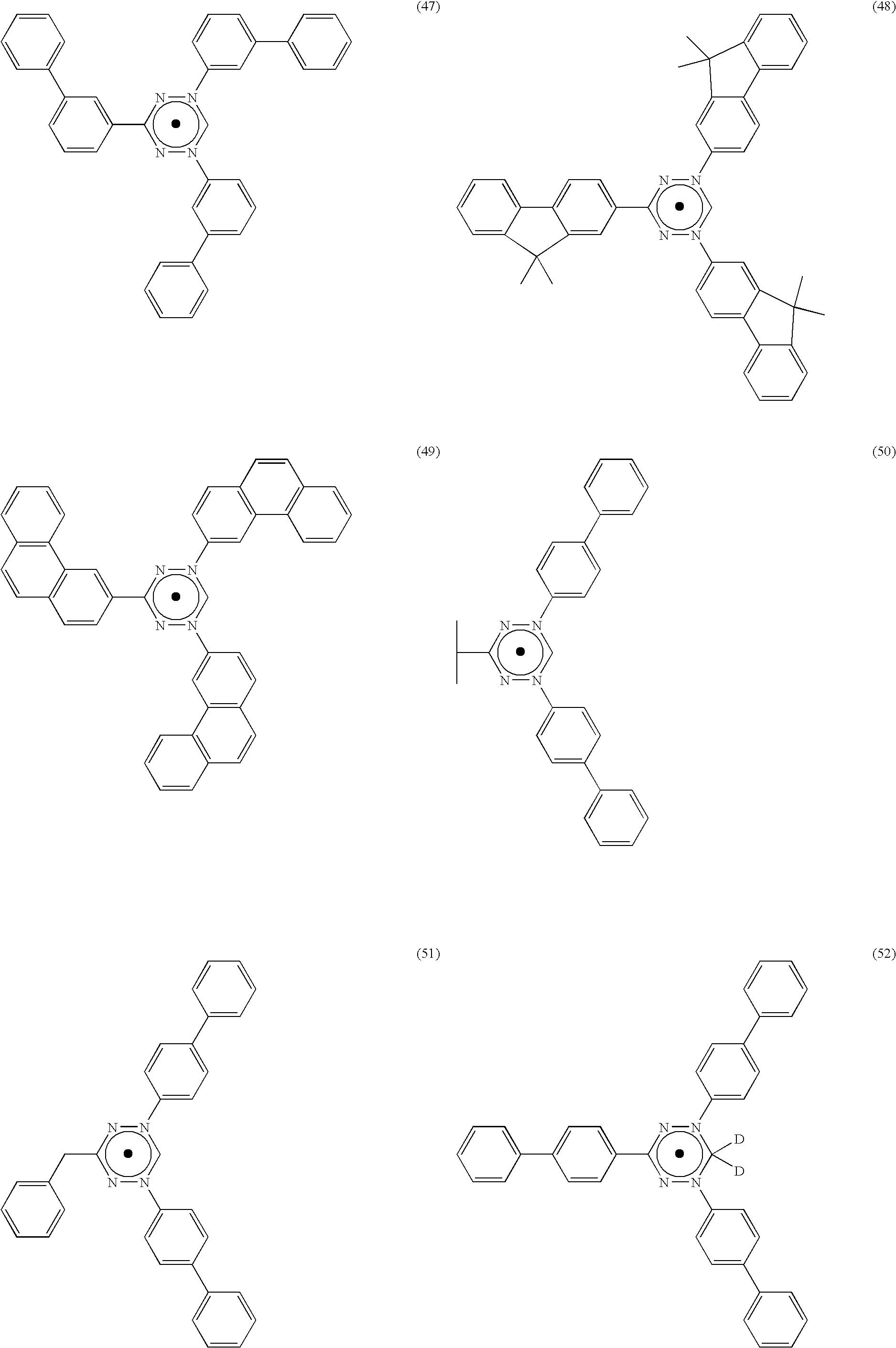

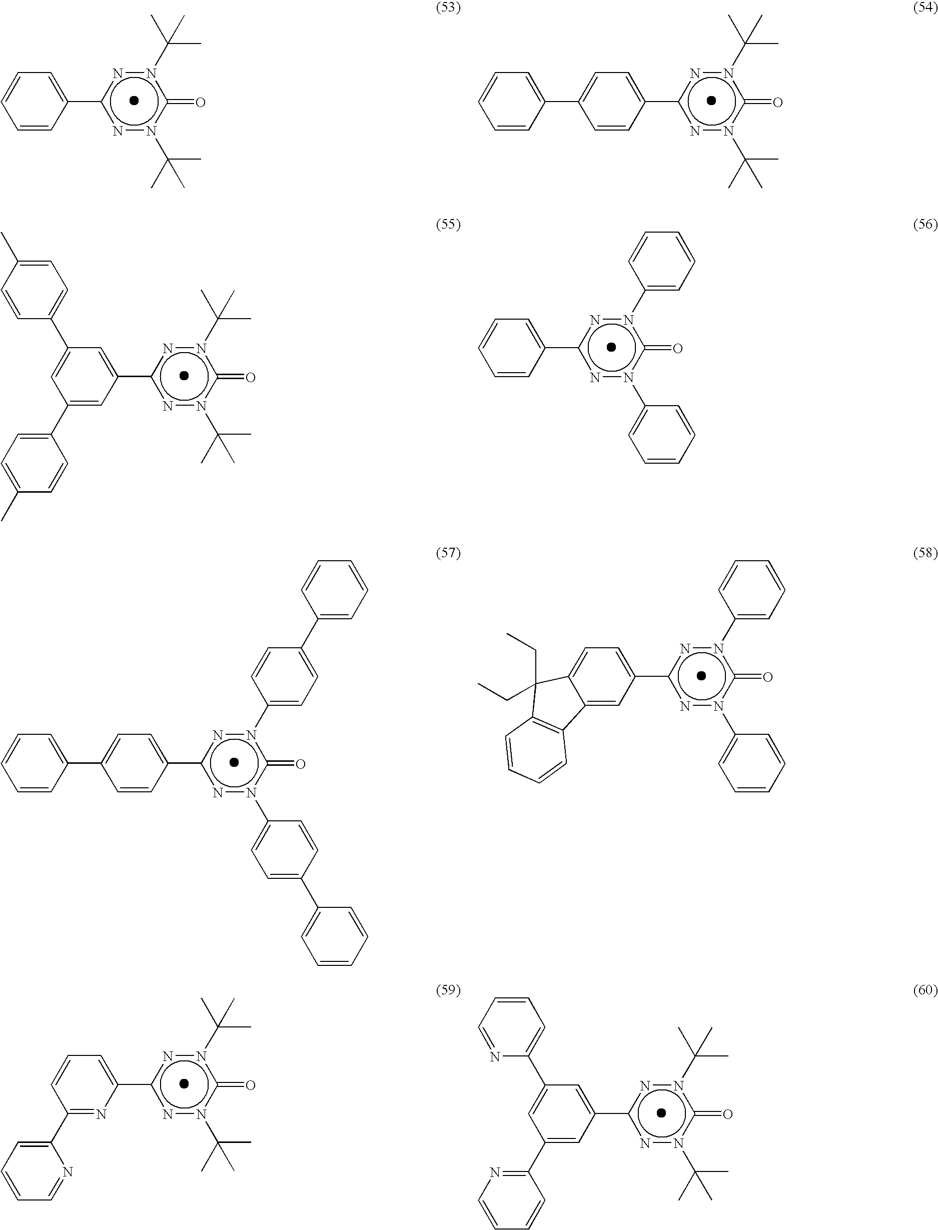

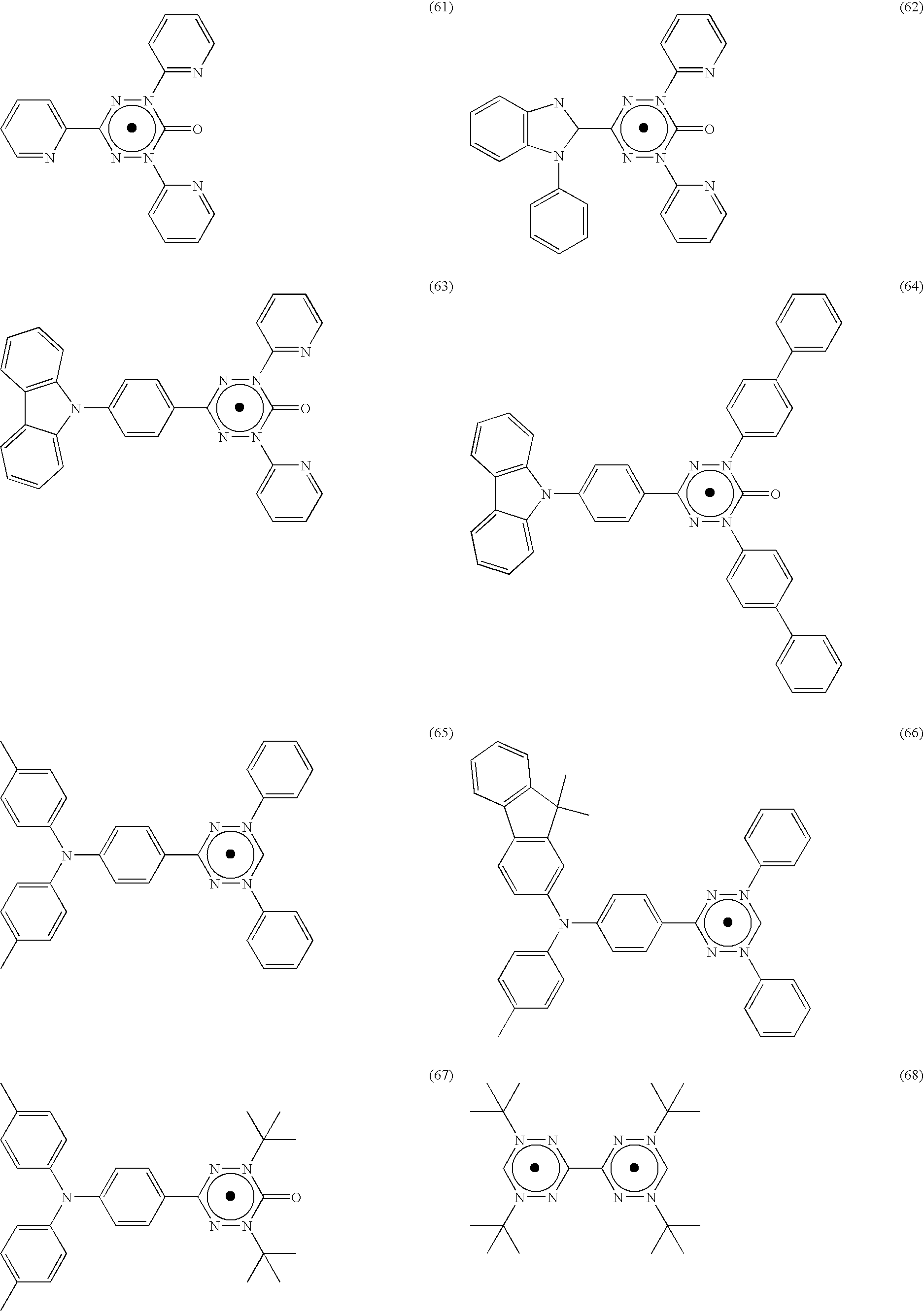

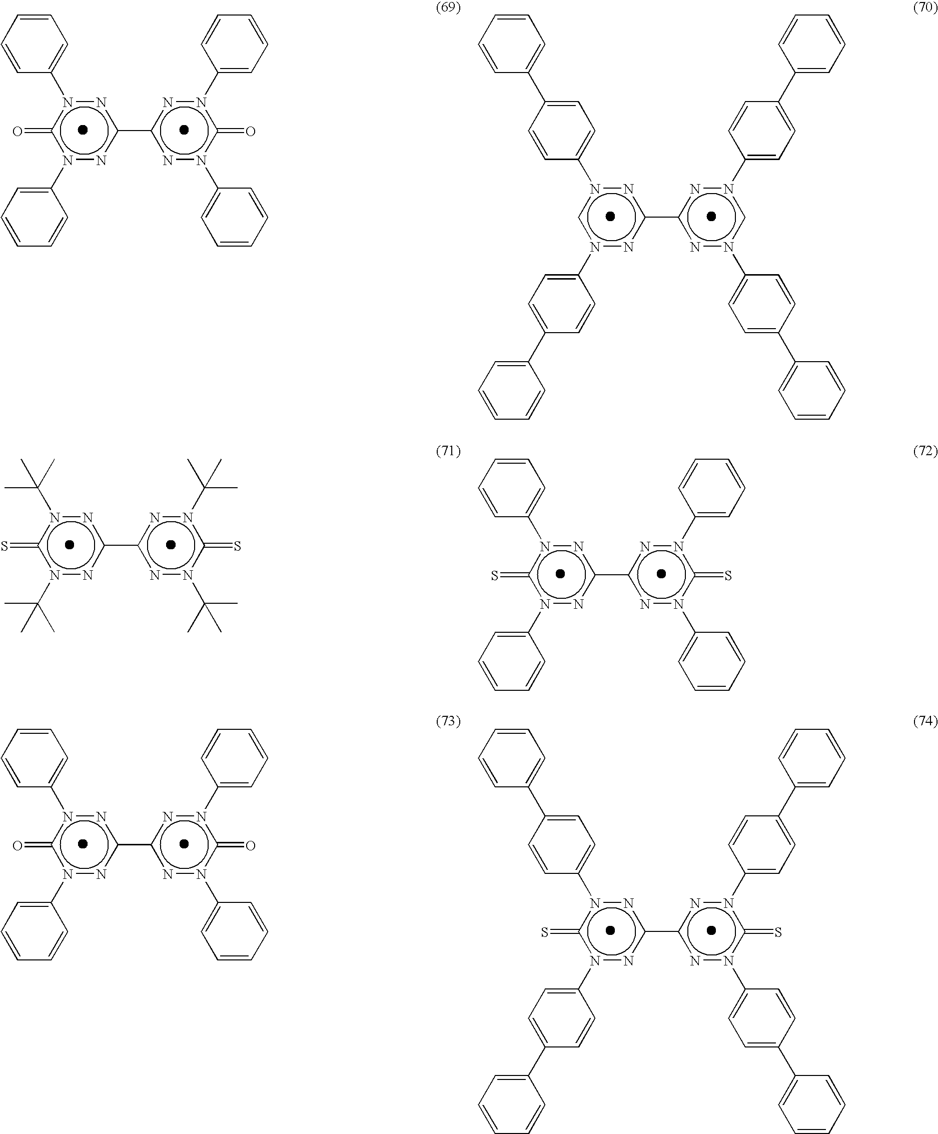

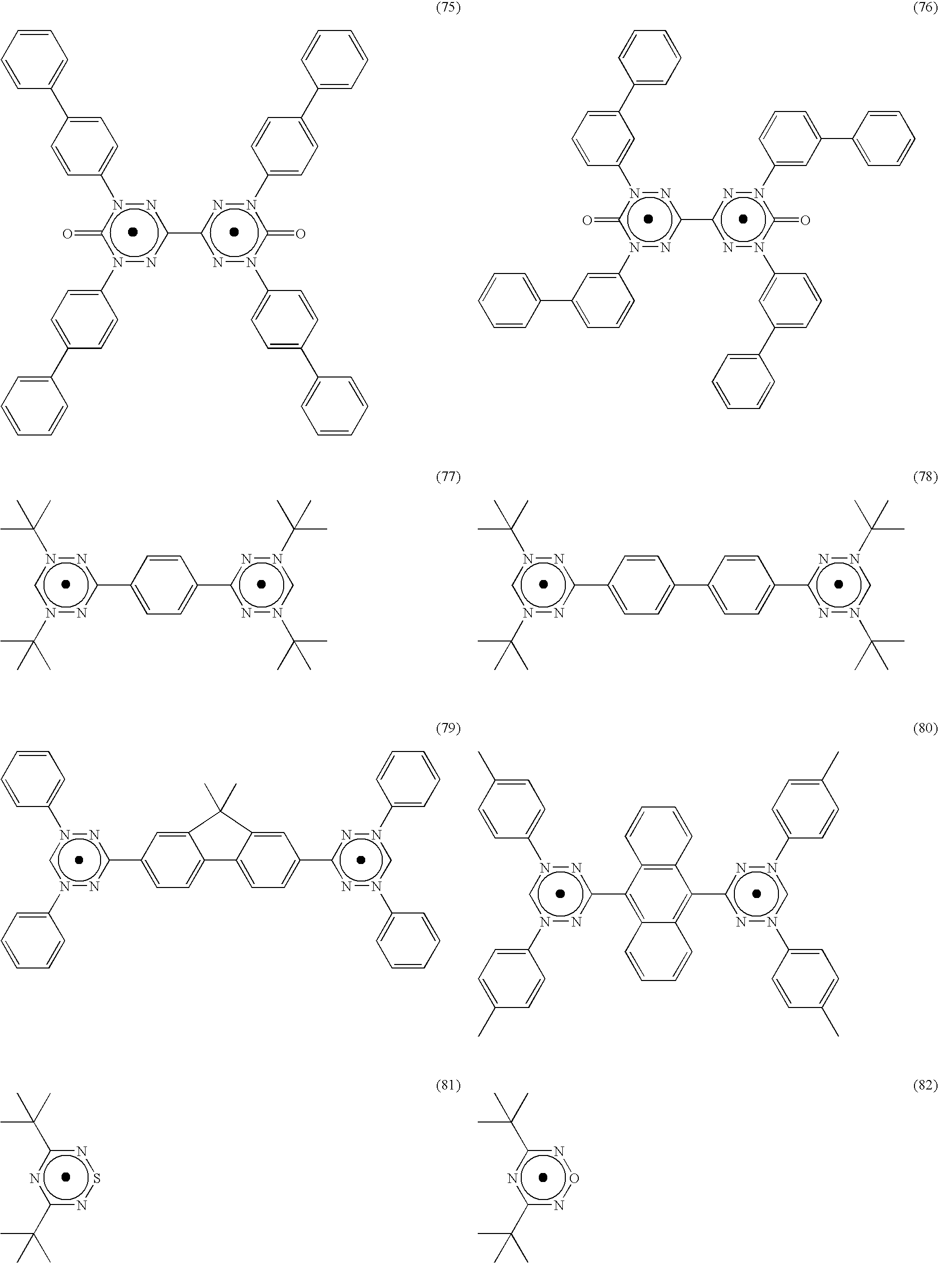

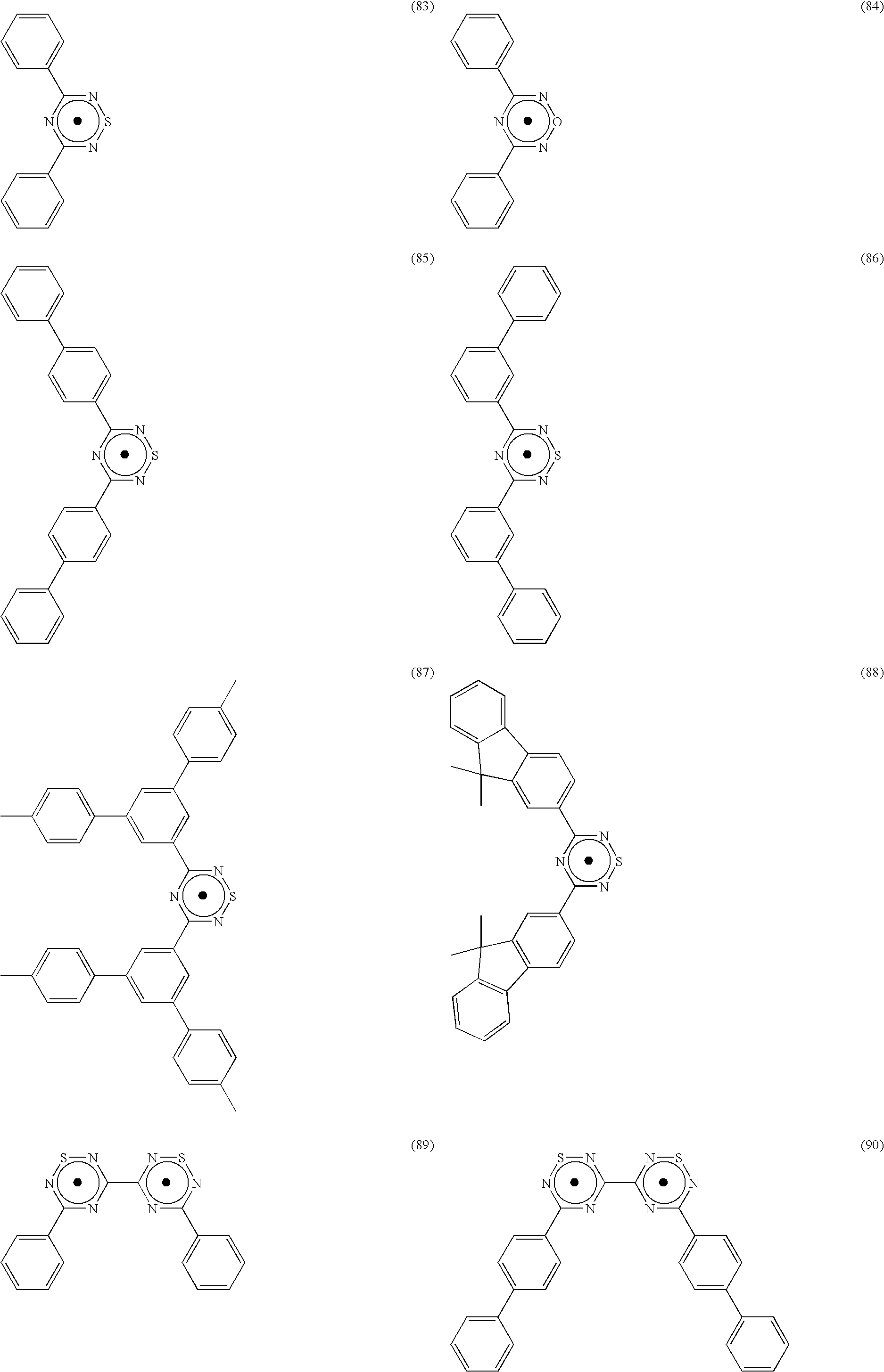

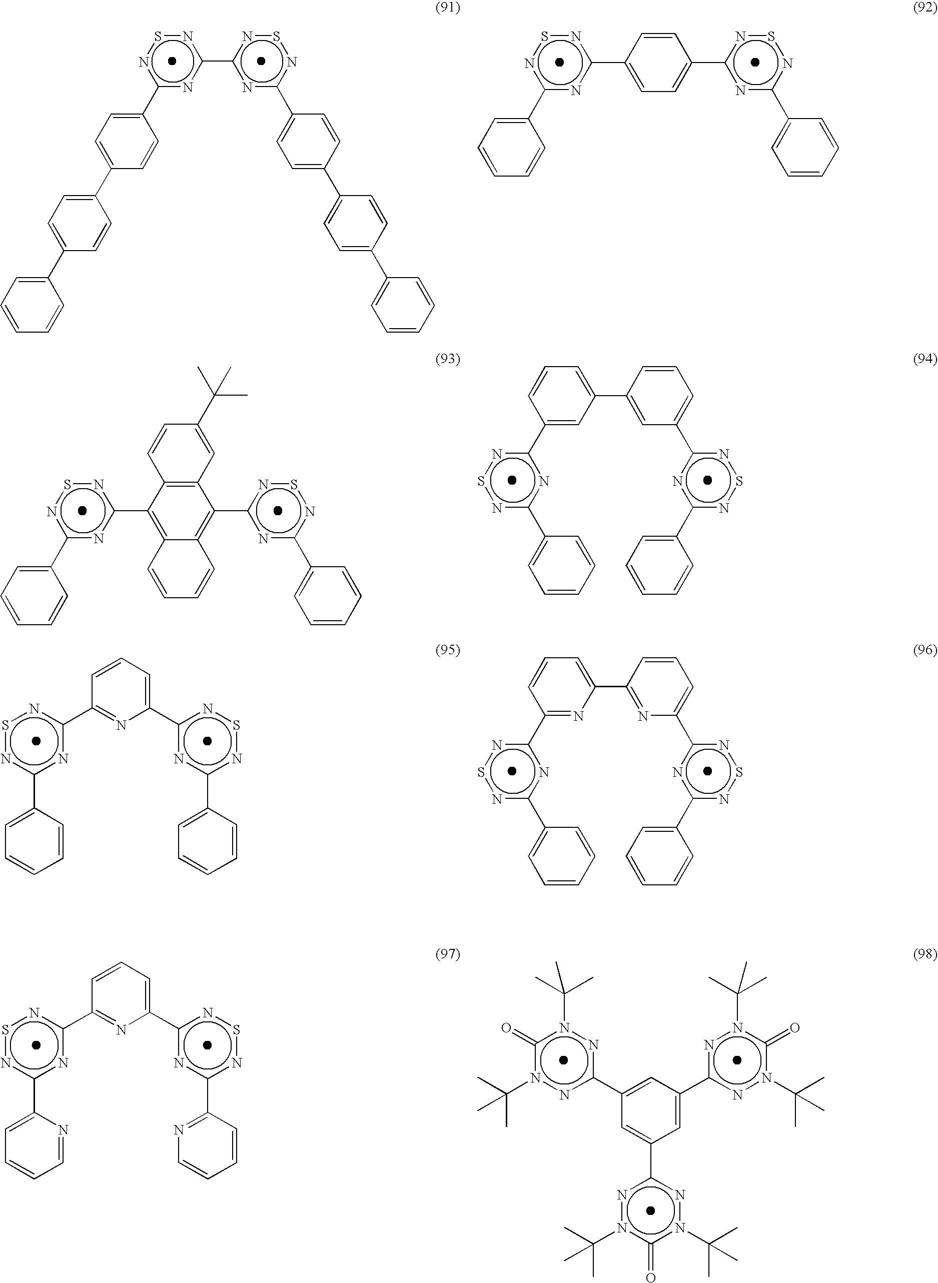

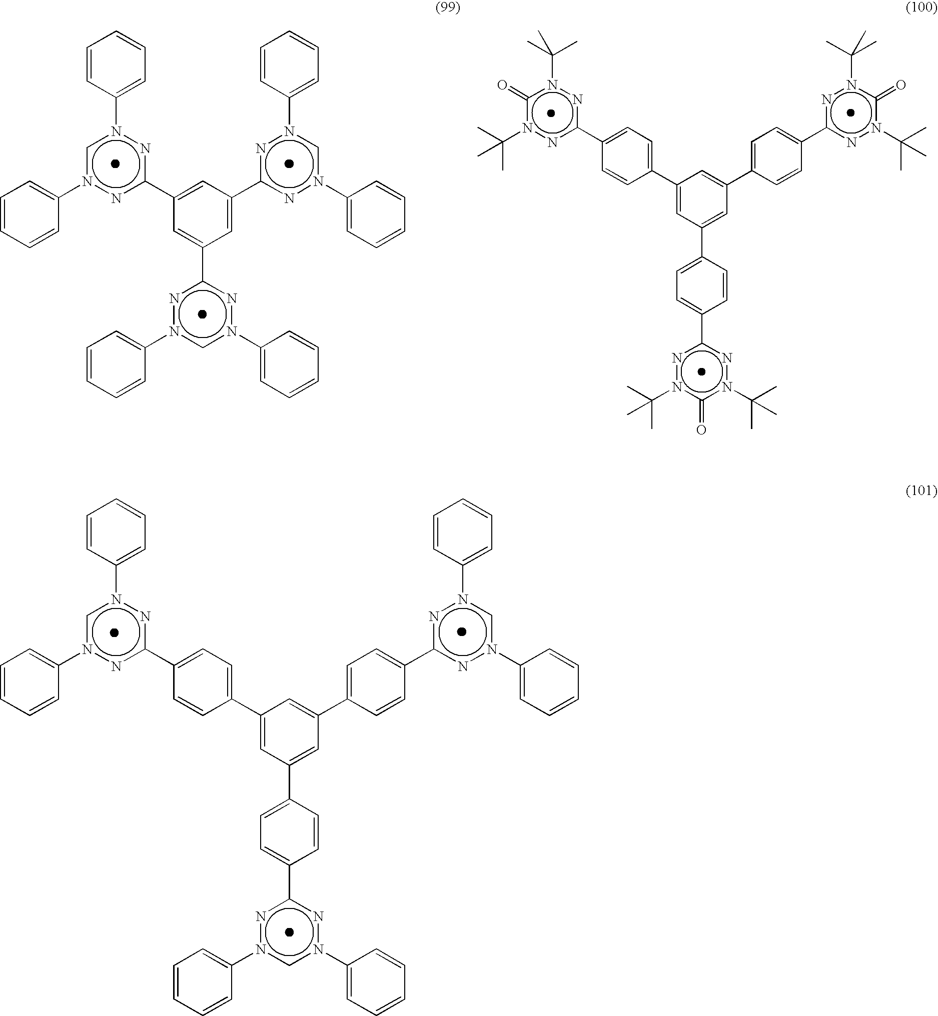

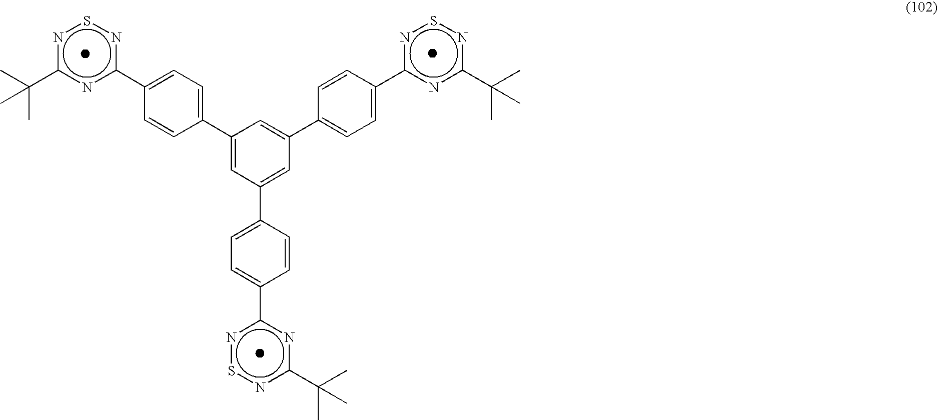

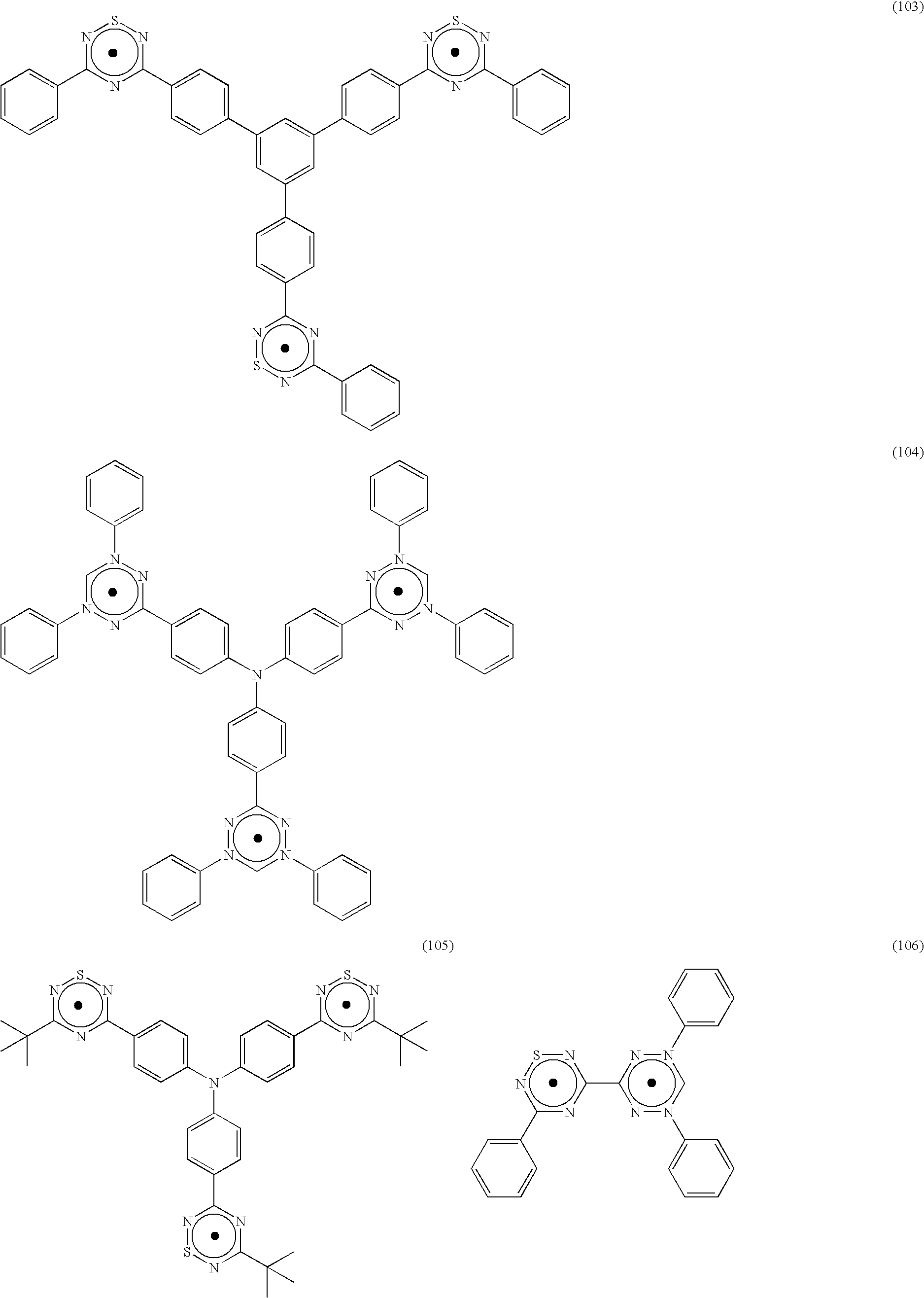

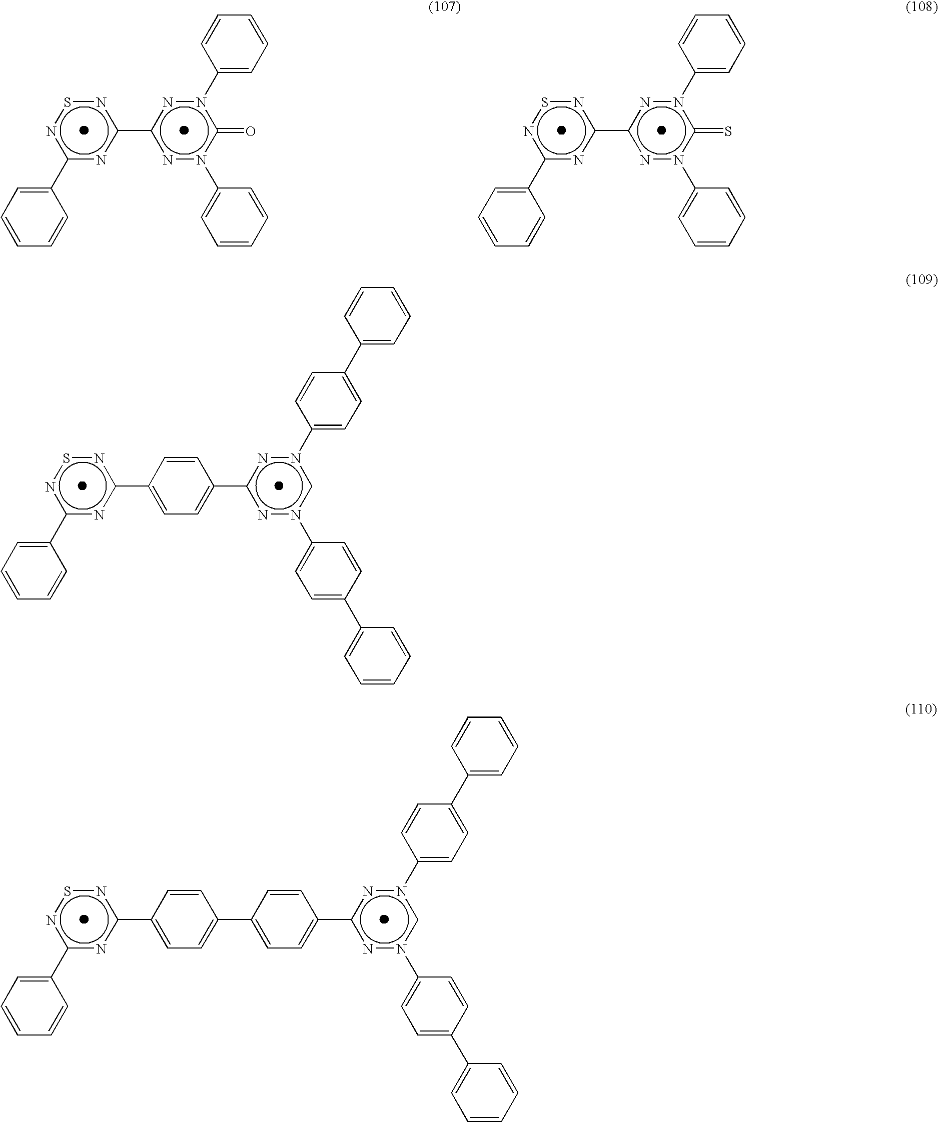

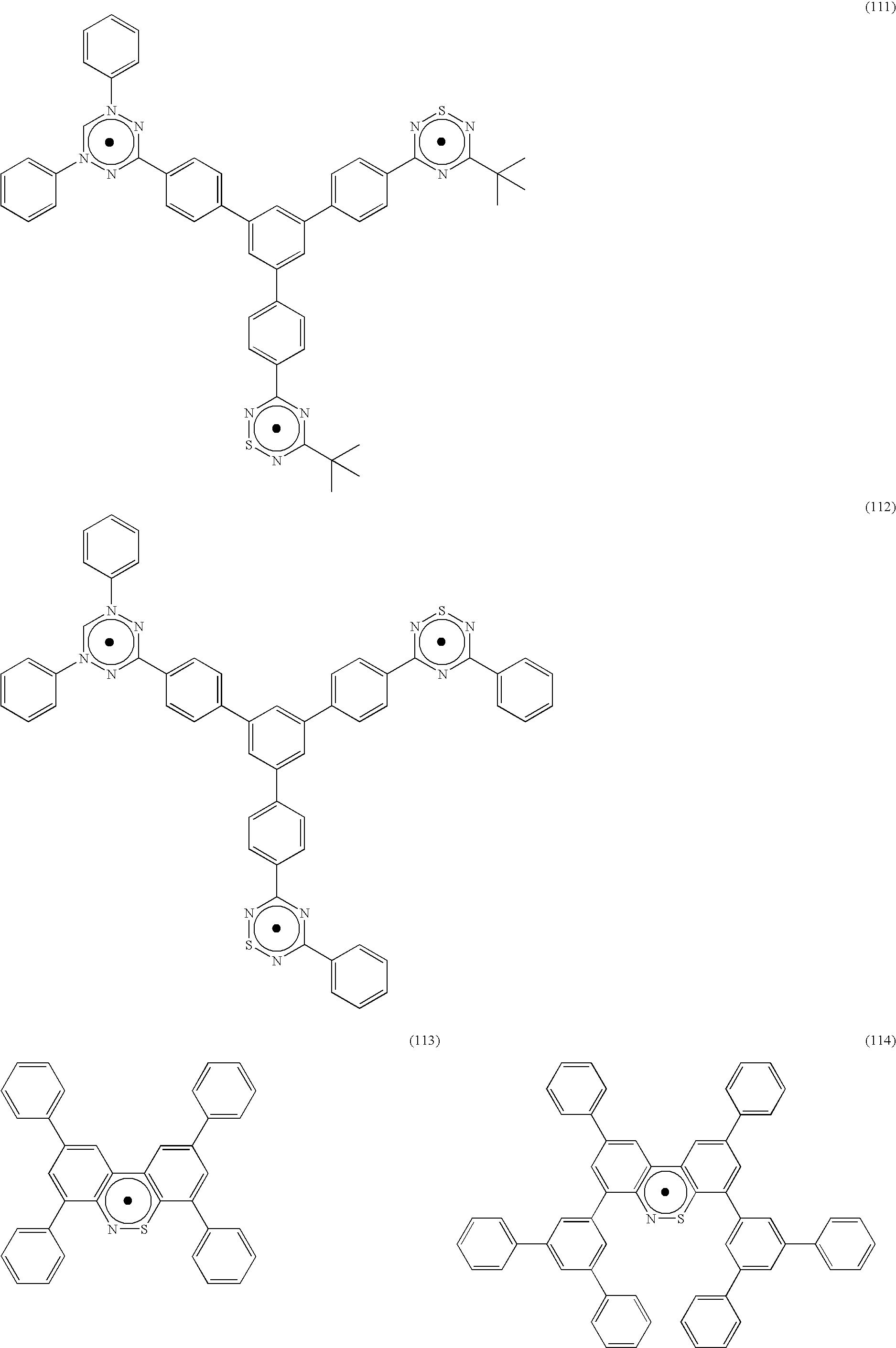

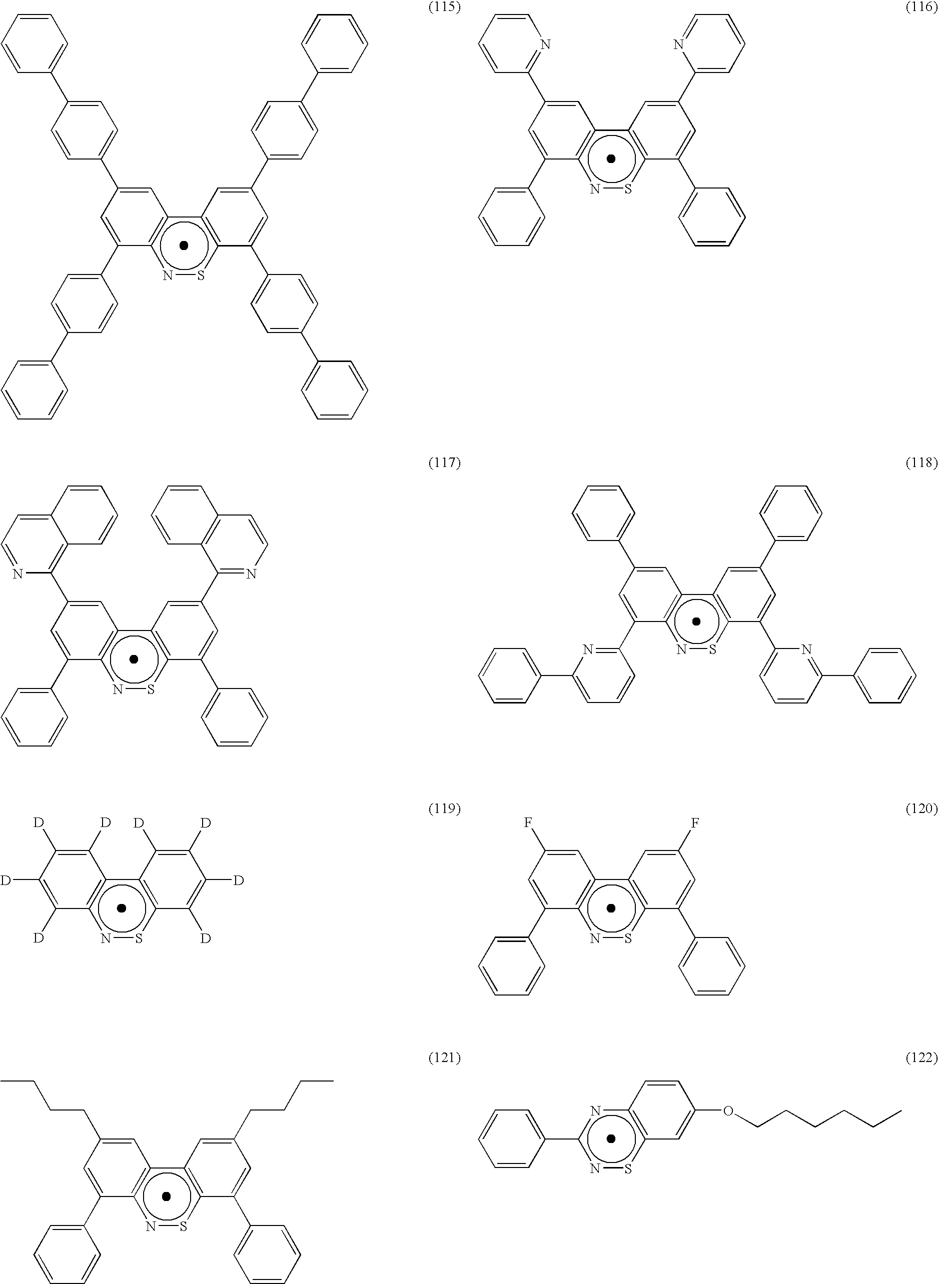

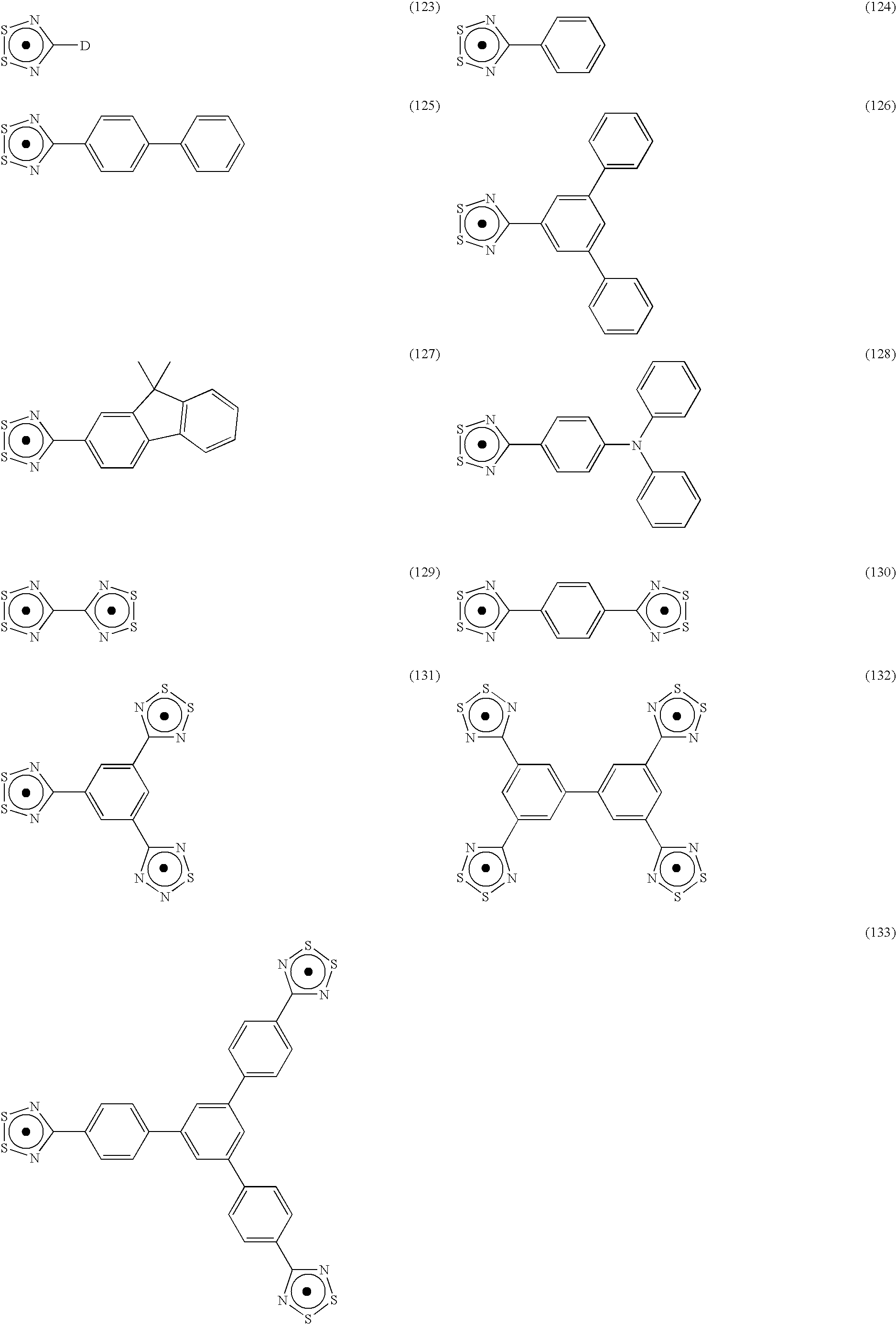

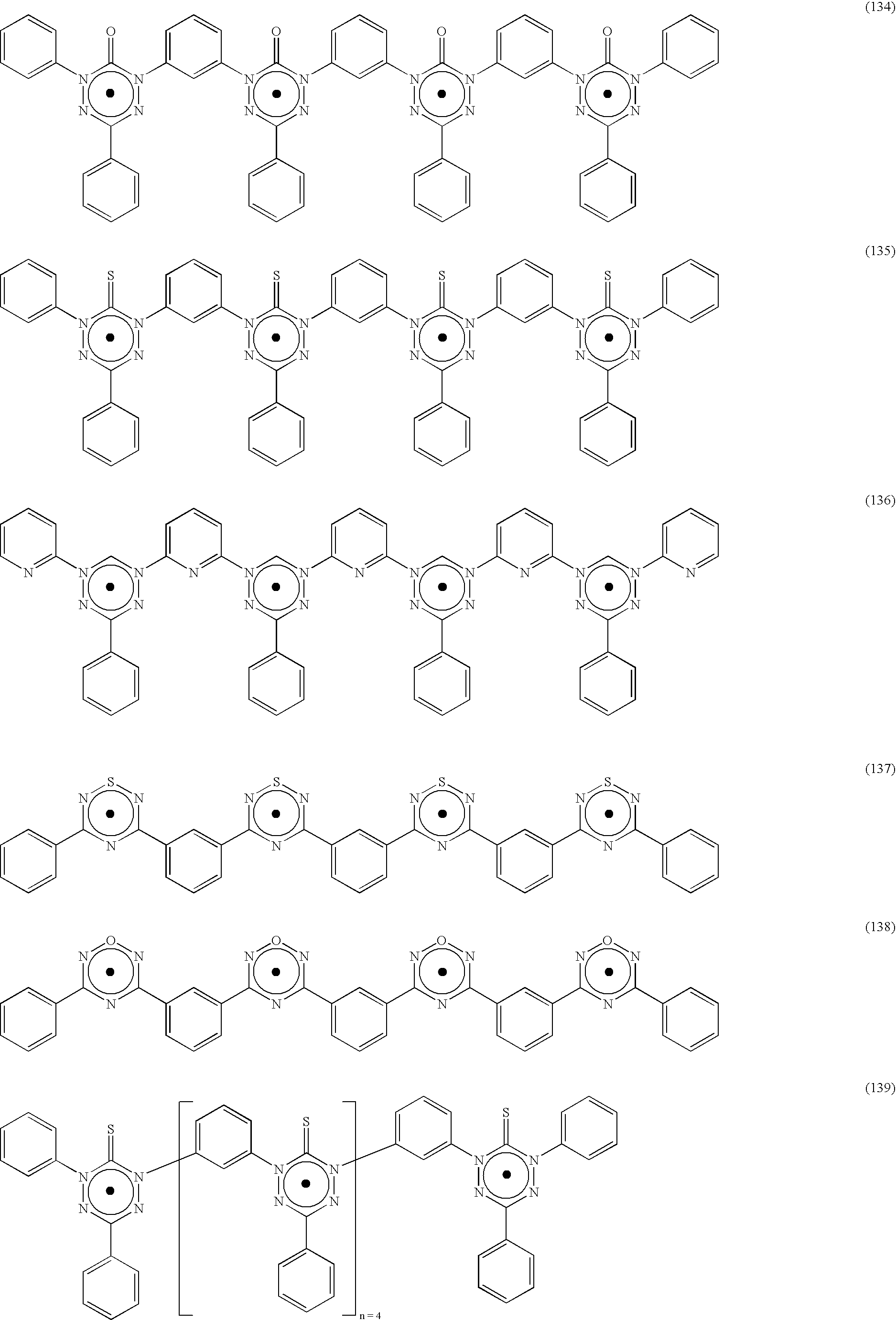

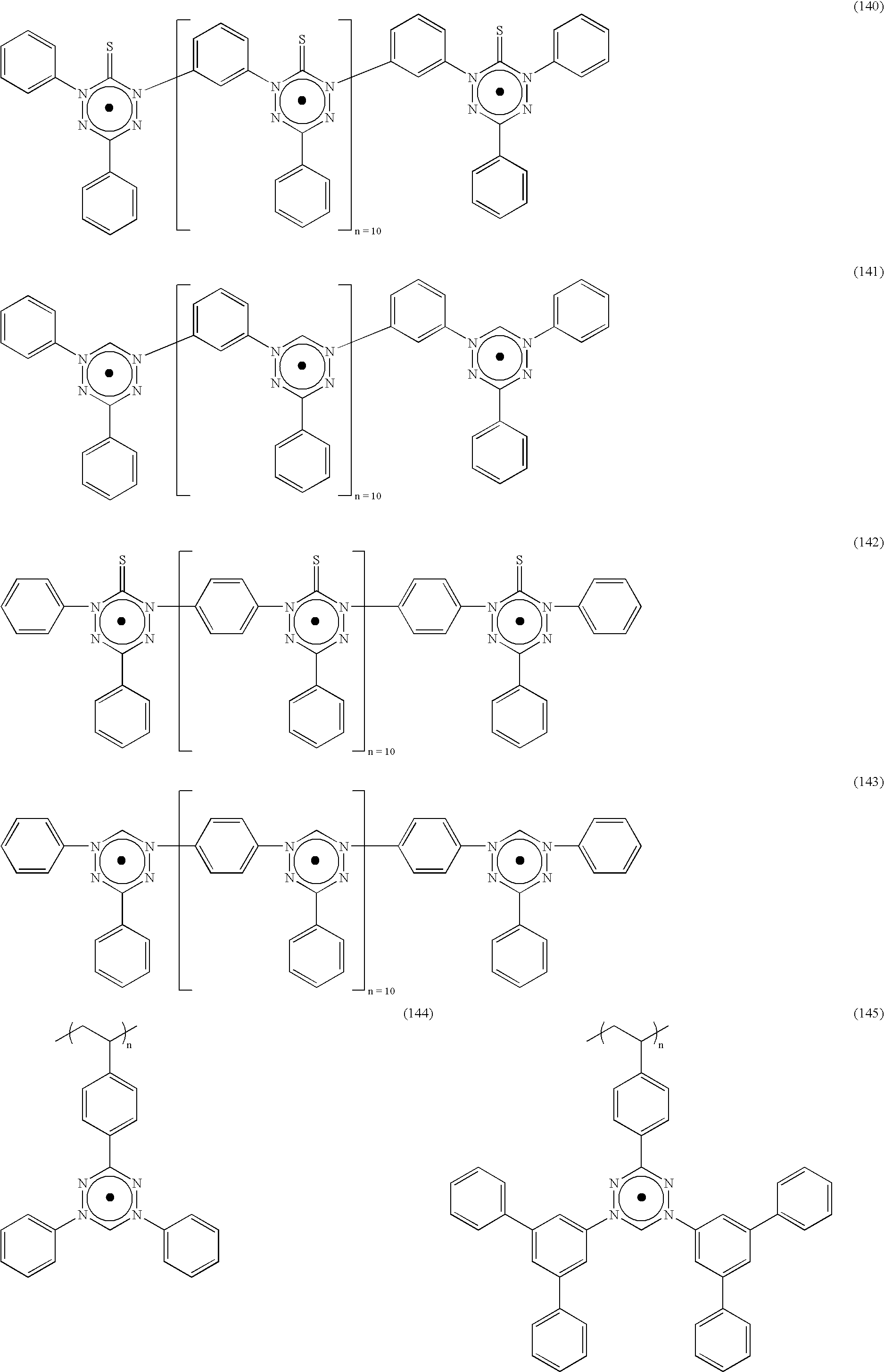

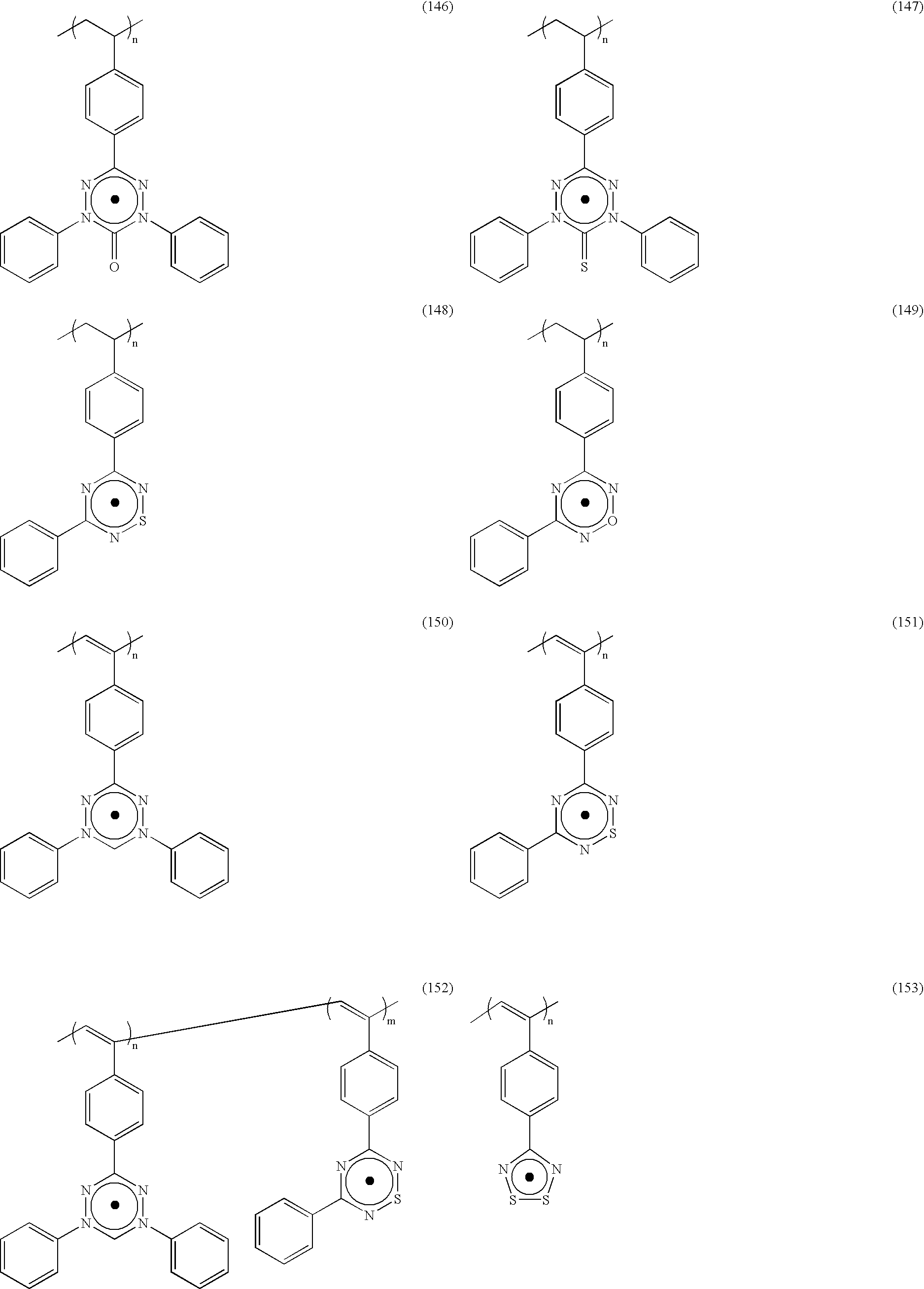

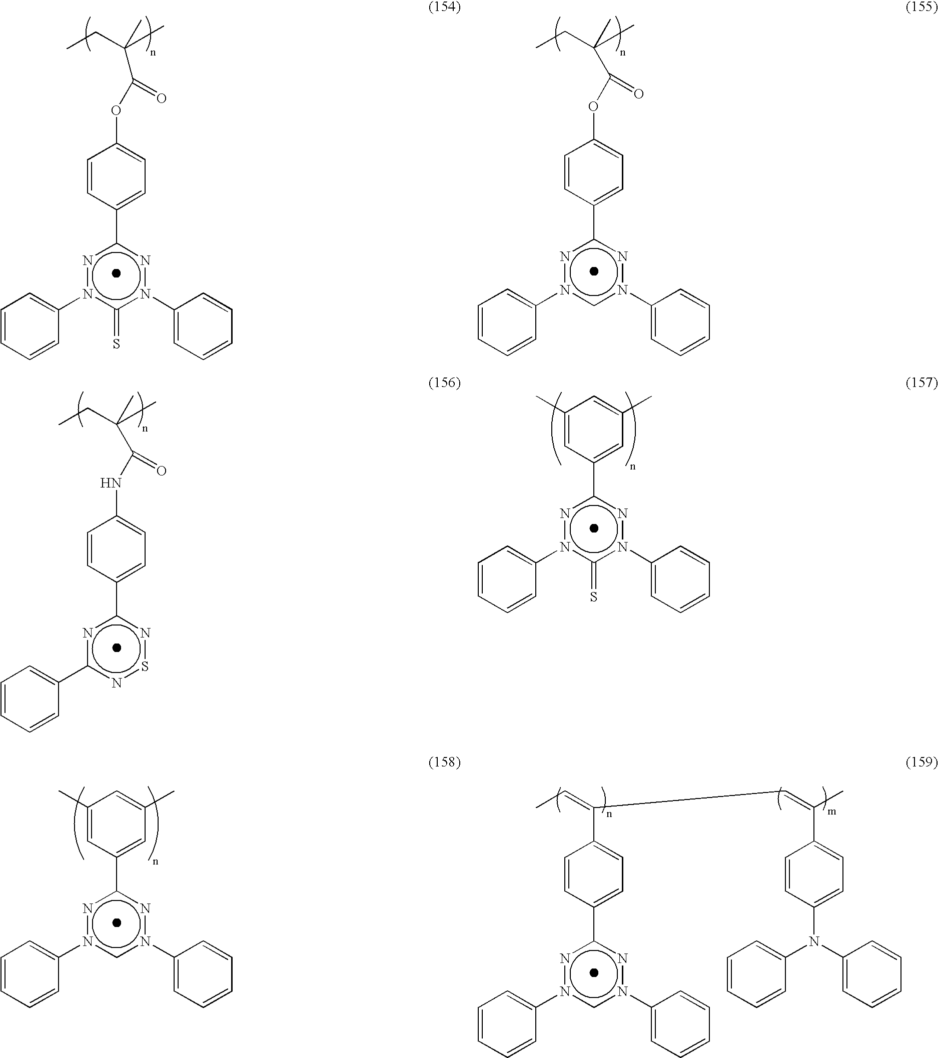

Next, the organic light emitting device of the present invention will be described in detail. The organic light emitting device of the present invention includes: a pair of electrodes having an anode and a cathode; and one or more organic layers each containing an organic compound, the one or more organic layers being interposed between the pair of electrodes, in which at least one layer of the organic layers each containing the organic compound includes, in the organic layer, organic radical compounds represented by general formulae (1) to (4), or organic radical compounds in which general formulae (1) to (4) are directly bonded or bonded via a bivalent or trivalent aromatic ring, heterocyclic ring, or aromatic amine, and a oligomer or polymer containing the structures represented by general formulae (1) to (4) as a partial structure.

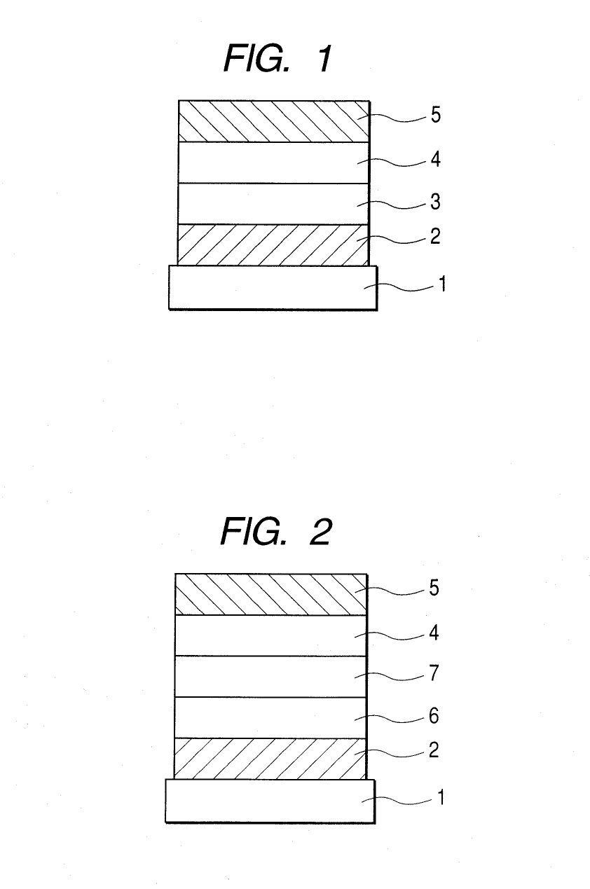

FIGS. 1 to 7 illustrate preferable examples of the organic light emitting device of the present invention.

First, reference numerals of the drawings will be described.

Reference numeral 1 denotes a substrate, 2 denotes an anode, 3 denotes a hole injecting and transporting layer containing an organic radical compound, 4 denotes an electron injecting and transporting-cum-light emitting layer, 5 denotes a cathode, 6 denotes a hole injecting layer containing an organic radical compound, 7 denotes a hole transporting layer, 8 denotes a light emitting layer, 9 denotes an electron injecting and transporting layer, 10 denotes an electron transporting layer, 11 denotes a hole injecting and transporting layer, 12 denotes an electron injecting and transporting layer containing an organic radical compound, 13 denotes an electron injecting layer containing an organic radical compound, 14 denotes a hole/exciton-blocking layer, and 15 denotes a light emitting layer containing an organic radical compound.

FIG. 1 is a cross sectional view illustrating an organic light emitting device according to one embodiment of the present invention. FIG. 1 illustrates an organic light emitting device with a structure in which the anode 2, the hole injecting and transporting layer 3 containing an organic radical compound, the electron injecting and transporting-cum-light emitting layer 4, and the cathode 5 are disposed in the stated order on the substrate 1. The hole injecting and transporting layer containing an organic radical compound is a multifunctional layer serving as anode activation, hole generation, and hole transportation.

FIG. 2 illustrates an organic light emitting device with a structure in which the anode 2, the hole injecting layer 6 containing an organic radical compound, the hole transporting layer 7, the electron injecting and transporting-cum-light emitting layer 4, and the cathode 5 are disposed in the stated order on the substrate 1. In this structure, this organic light emitting device has separate hole injecting function and hole transporting function, and the hole injecting layer containing organic radical compounds forming the device is a multifunctional layer serving as anode activation, hole generation, and hole transportation.

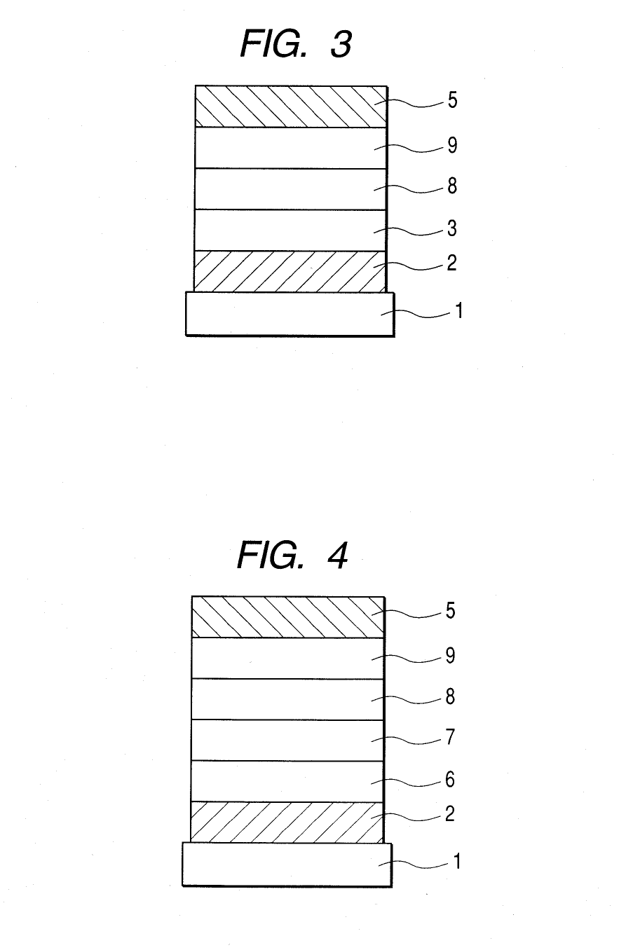

FIG. 3 illustrates an organic light emitting device with a structure in which the anode 2, the hole injecting and transporting layer 3 containing an organic radical compound, the light emitting layer 8, the electron injecting and transporting 9, and the cathode 5 are disposed in the stated order on the substrate 1. In this structure, this organic light emitting device has separate electron transporting function and light emitting function. The hole injecting and transporting layer containing organic radical compounds forming the device is a multifunctional layer serving as anode activation, hole generation, and hole transportation.

FIG. 4 illustrates an organic light emitting device with a structure in which the anode 2, the hole injecting layer 6 containing an organic radical compound, the hole transporting layer 7, the light emitting layer 8, the electron injecting and transporting layer 9, and the cathode 5 are disposed in the stated order on the substrate 1. In this structure, this organic light emitting device has separate carrier transporting function and light emitting function similarly as in the structure shown in FIG. 3. The hole injecting layer containing organic radical compounds forming the device is a multifunctional layer serving as anode activation, hole generation, and hole transportation.

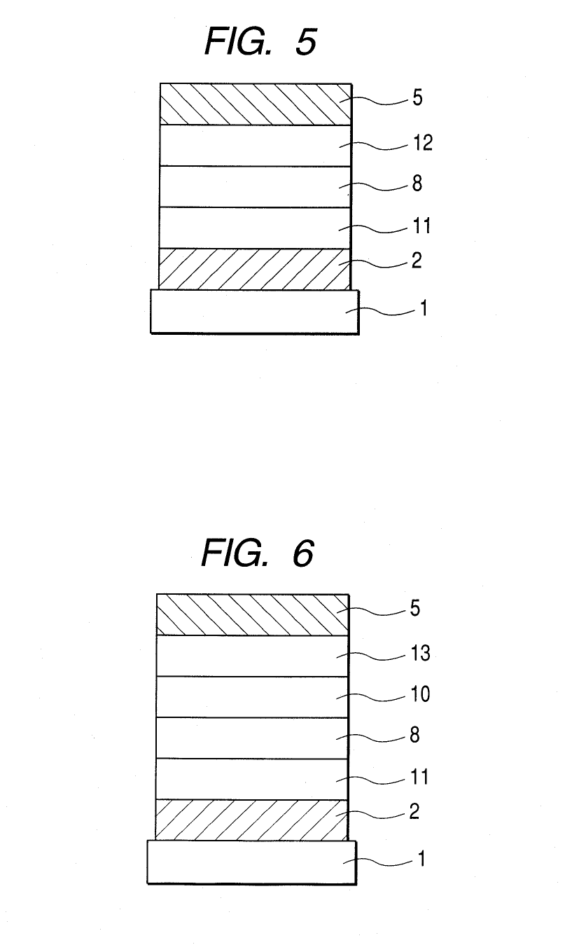

FIG. 5 illustrates an organic light emitting device with a structure in which the anode 2, the hole injecting and transporting layer 11, the light emitting layer 8, the electron injecting and transporting layer 12 containing an organic radical compound, and the cathode 5 are disposed in the stated on the substrate 1. The electron injecting and transporting layer containing organic radical compounds forming the device is a multifunctional layer serving as electron injection, electron transportation, and hole/exciton blocking.

FIG. 6 illustrates an organic light emitting device with a structure in which the anode 2, the hole injecting and transporting layer 11, the light emitting layer 8, the electron transporting layer 10, the electron injecting layer 13 containing an organic radical compound, and the cathode 5 are disposed in the stated order on the substrate 1. The electron injecting layer containing organic radical compounds forming the device is a multifunctional layer serving as cathode activation, electron injection, and electron transportation.

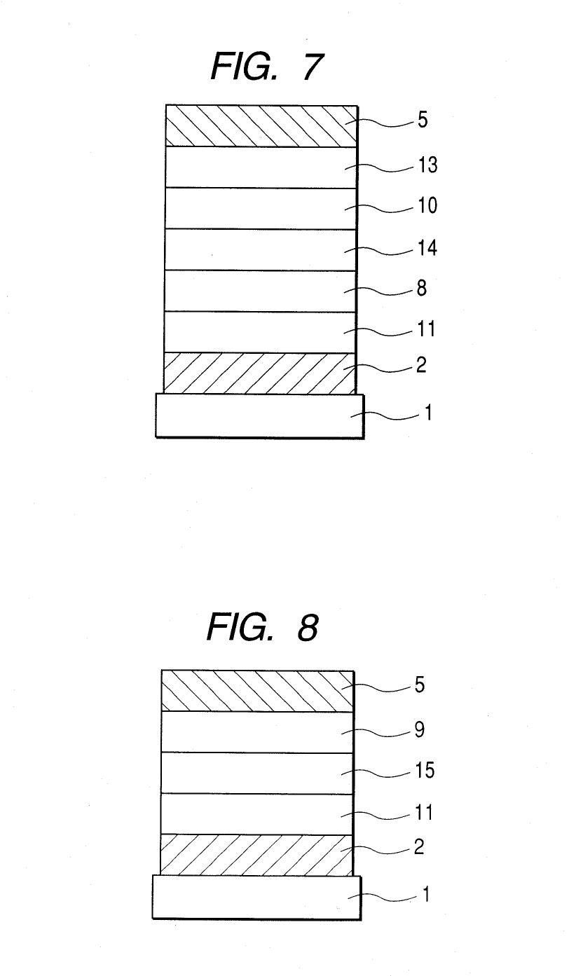

FIG. 7 illustrates an organic light emitting device with a structure in which a layer for blocking travel of a hole or exciton to a side of the cathode 5 (a hole/exciton-blocking layer 14) is inserted between the light emitting layer 8 and the electron transporting layer 10, unlike FIG. 6. This structure uses a compound having an extremely high ionization potential for the hole/exciton-blocking layer 14 and is effective for improving light emitting efficiency.

FIG. 8 illustrates an organic light emitting device with a structure in which the anode 2, the hole injecting and transporting layer 11, the light emitting layer 15 containing an organic radical compound, the electron injecting and transporting layer 9, and the cathode 5 are disposed in the stated order on the substrate 1.

It should be noted that FIG. 1 or FIG. 8 illustrate very basic device structures, and the structure of the organic light emitting device using the organic radical compound of the present invention is not limited to the above. The device structure may take various structures, and, for example: may take a top emission structure in which light is emitted from an opposite side of the substrate; may take a structure in which an insulating layer is disposed on an interface between the light emitting electrode and the organic layer; and may take a structure in which an adhesive layer or an interference layer is provided.

There is also no limitation on the manner of use of the organic radical compound in the above-mentioned device structure, and, for example, different organic radical compounds can be used alone or as a mixture with another organic compound for both the hole injecting layer and the electron injecting layer. Moreover, the organic radical compound may be incorporated in the light emitting layer, thereby controlling the carrier balance of the whole device.

Further, in the case of using the organic radical compound in a layer that is in contact with the electrode (metal or inorganic compound) similarly as the hole injecting layer or the electron injecting layer, the organic radical compound is chemically bonded to the electrode, thereby improving carrier injecting ability. For example, for a positive electrode, there are used: simple metals such as gold, platinum, silver, and copper; alloys thereof; and metal oxides such as tin oxide, zinc oxide, indium oxide, indium tin oxide (ITO), and indium zinc oxide. The above-mentioned metals or metal oxides can be bonded to the organic radical compound via a connecting group such as —O—, —S—, —Si(R₂)—O—, or —P(═O)—O—. In this case, it is preferable to use an organic radical compound containing a substituent having —OH, —SH, —Si(R₂) OH, or —P(═O)OH in advance (R represents an arbitrary substituent, for example, an alkyl group). The electrode surface (e.g., ITO surface) is subjected to acid treatment for activation (formation of —OH), thereby performing the above-mentioned reaction.

In the present invention, conventionally known organic radical compounds, such as a low molecular weight or polymer hole transporting compounds, light emitting compounds, or electron transporting compounds can be used together with the organic radical compound of the present invention as required.

A preferred hole injecting and transporting material has excellent mobility for facilitating injection of a hole from an anode and for transporting the injected hole to a light emitting layer. Examples of the low molecular weight or polymer material having a hole injecting and transporting properties include, but are not limited to: a triarylamine derivative; a phenylenediamine derivative; a triazole derivative; an oxadiazole derivative; an imidazole derivative; a pyrazoline derivative; a pyrazolone derivative; an oxazole derivative; a fluorenone derivative; a hydrazone derivative; a stilbene derivative; a phthalocyanine derivative; a porphyrin derivative; poly(vinylcarbazole); poly(silylene); poly(thiophene); and other conductive polymers. Some specific examples will be shown below.

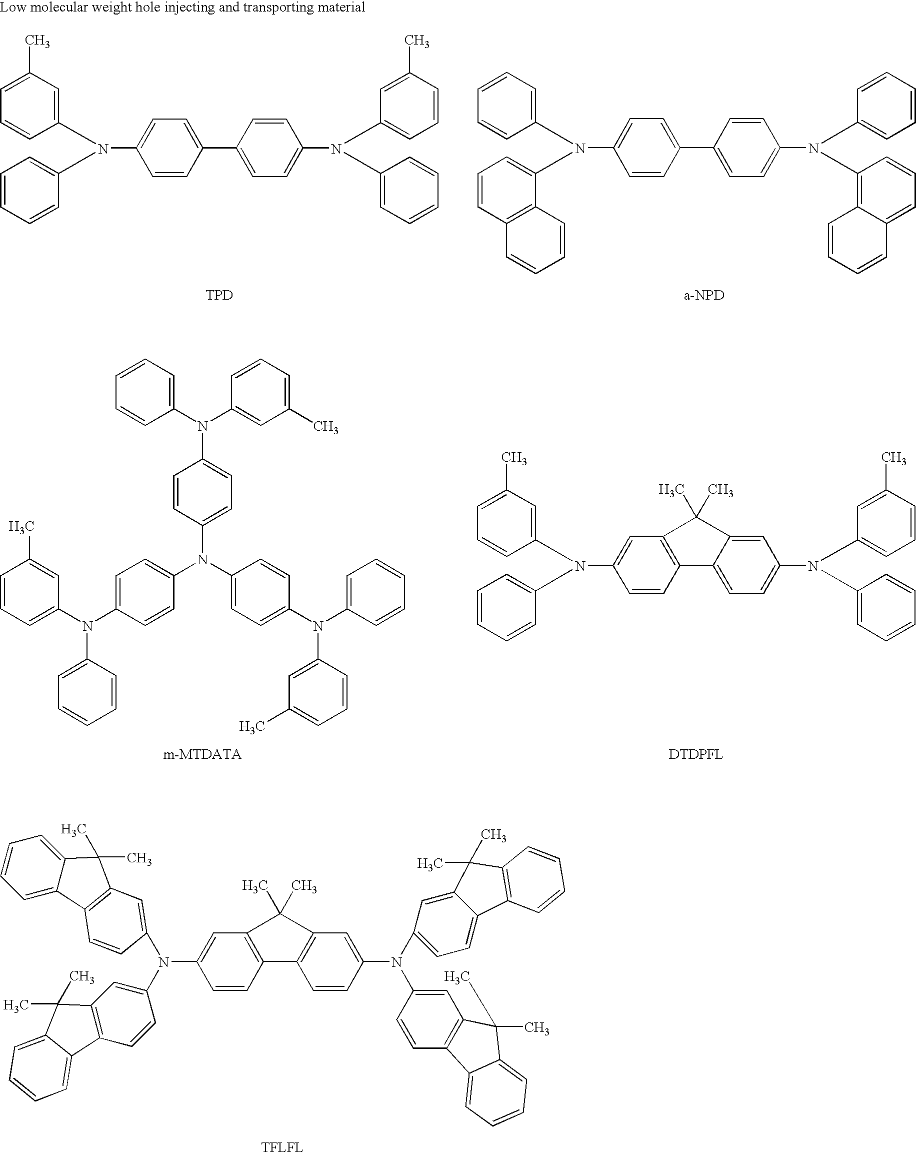

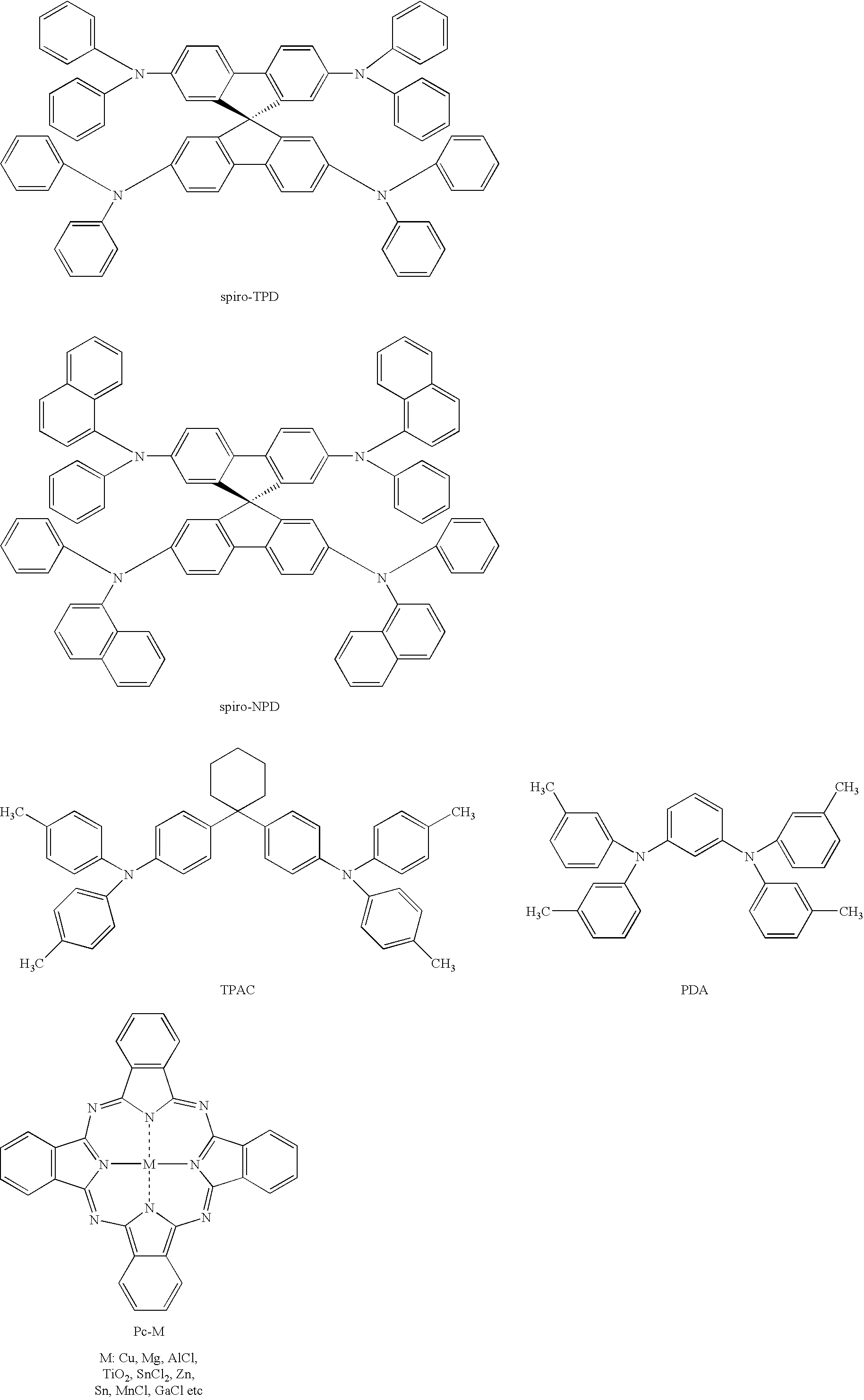

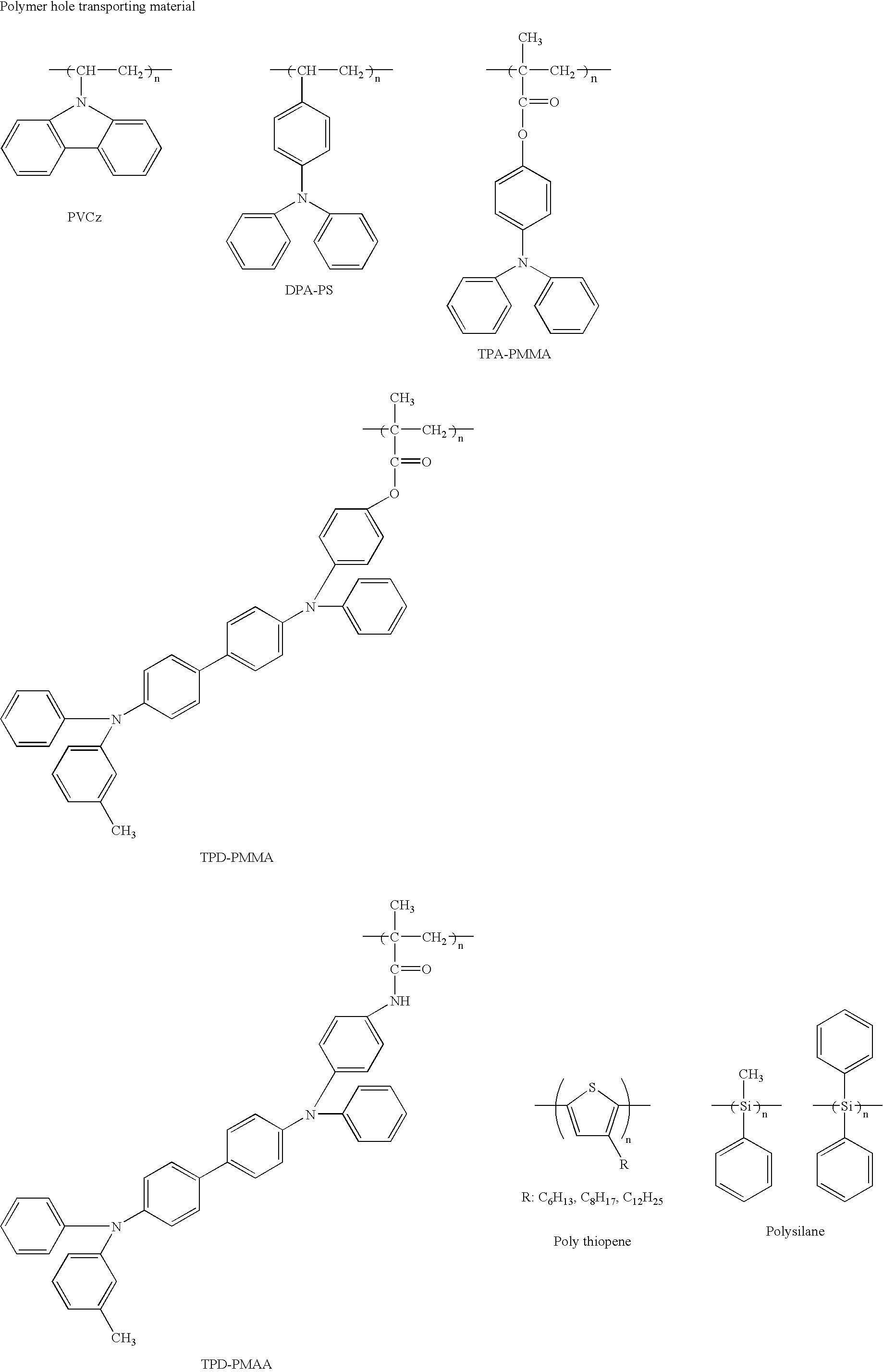

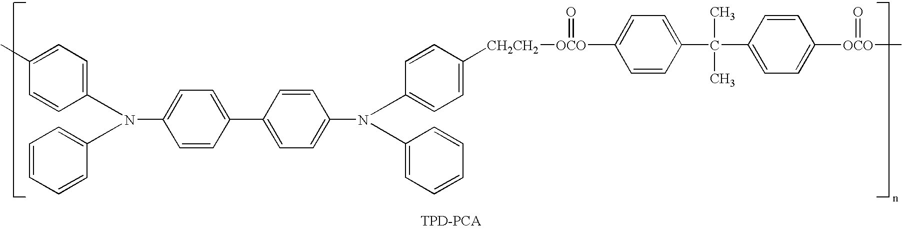

Examples of the material which is involved in a light emitting function include, but are not limited to: a polycyclic condensed aromatic compound (e.g., a naphthalene derivative, a phenanthrene derivative, a fluorene derivative, a pyrene derivative, a tetracene derivative, a coronene derivative, a chrysene derivative, a perylene derivative, a 9,10-diphenylanthracene derivative, or rubrene); a quinacridone derivative; an acridone derivative; a coumarin derivative; a pyran derivative; Nile red; a pyrazine derivative; a benzoimidazole derivative; a benzothiazole derivative; a benzoxazole derivative; a stilbene derivative; an organometallic complex (e.g.: an organic aluminum complex such as tris(8-quinolinolato)aluminum; or an organic beryllium complex); and a polymer derivative such as a poly(phenylene vinylene)derivative, a poly(fluorene) derivative, a poly(phenylene) derivative, a poly(thienylene vinylene)derivative, or a poly(acetylene) derivative.

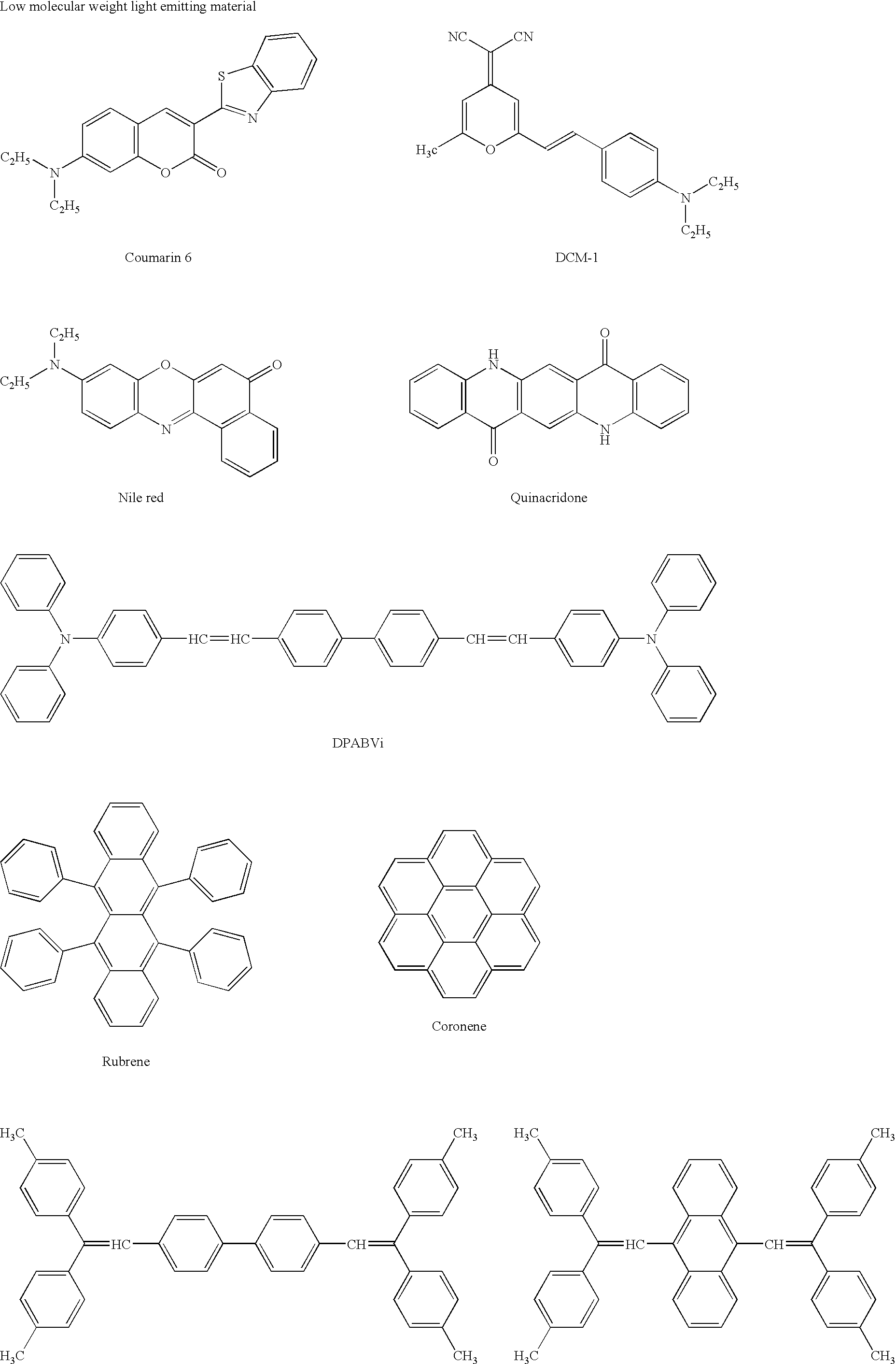

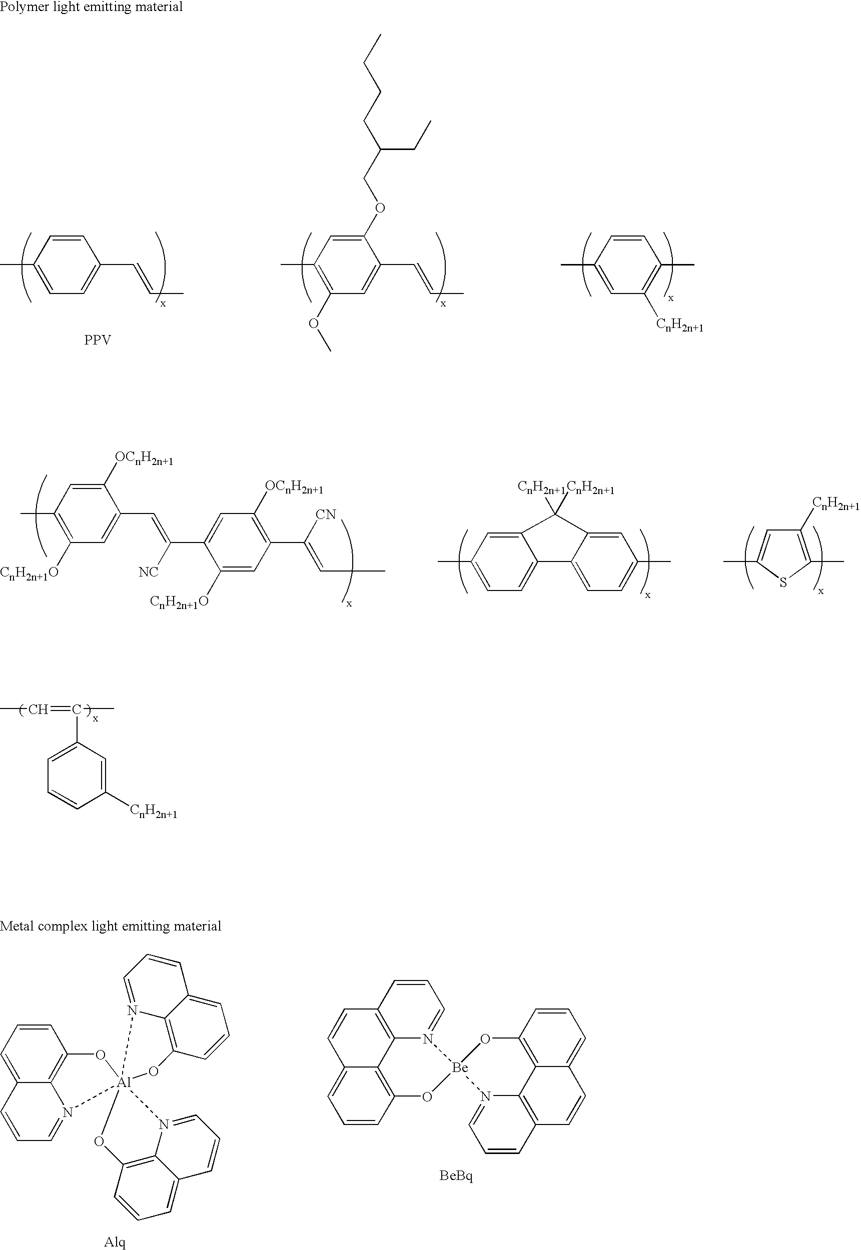

The electron injecting and transporting material may be arbitrarily selected from materials which facilitate injection of an electron from a cathode and which have a function of transporting the injected electron into a light emitting layer. The material is selected in consideration of, for example, the balance with the mobility of a carrier of the hole transporting material. Examples of the material having an electron injecting and transporting properties include, but are not limited to, an oxadiazole derivative, an oxazole derivative, a thiazole derivative, a thiadiazole derivative, a pyrazine derivative, a triazole derivative, a triazine derivative, a perylene derivative, a quinoline derivative, a quinoxaline derivative, a fluorenone derivative, an anthrone derivative, a phenanthroline derivative, and an organometallic complex. Some specific examples will be shown below.

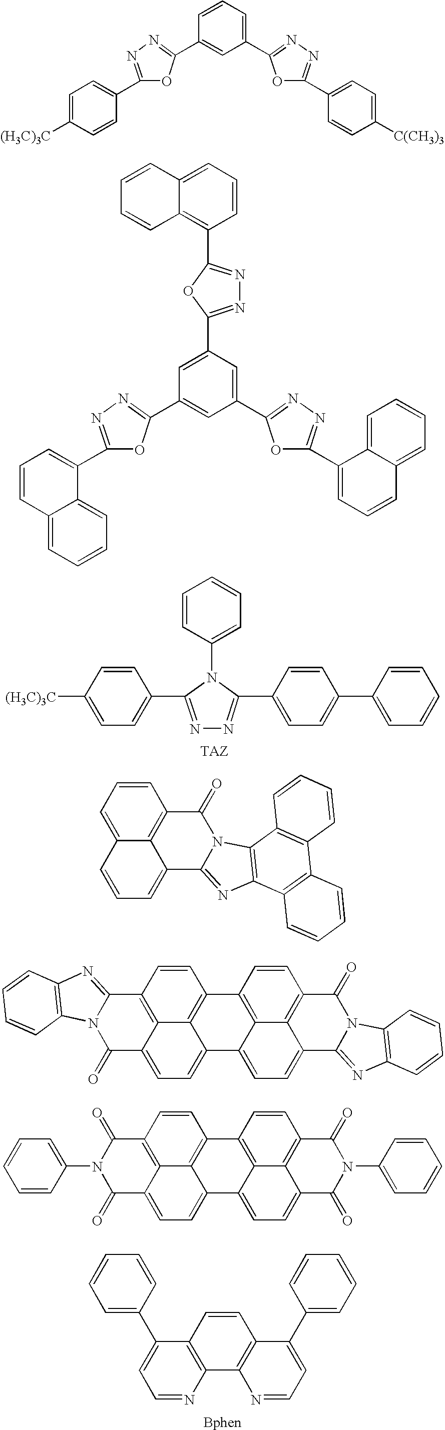

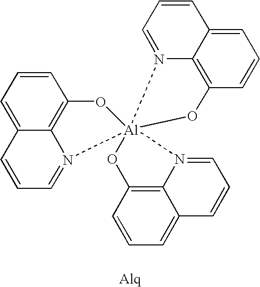

In the organic light emitting device of the present invention, the organic layer containing the organic radical compound and other organic layers are each formed by the following method. A thin film is formed by a vacuum deposition method, an ionized deposition method, sputtering, plasma, or a known coating method in which a compound is dissolved in an appropriate solvent. Examples of the coating method include a spin coating, dipping, casting, LB, inkjet method, or laser transfer method. In film formation by a coating method, in particular, a film may be formed by using a compound in combination with an appropriate binder resin. In the case of a low molecular weight organic radical compound, a plurality of organic radical compounds can be simultaneously deposited using a plurality of vapor deposition sources.

The binder resin may be selected from a wide variety of binder resins. Examples of the binder resin include, but not limited to: a polyvinyl carbazole resin; a polycarbonate resin; a polyester resin; a polyallylate resin; a polystyrene resin; an ABS resin; a polybutadiene resin; a polyurethane resin; an acrylic resin; a methacrylic resin; a butyral resin; a polyvinyl acetal resin; a polyamide resin; a polyimide resin; a polyethylene resin; a polyethersulfone resin; a diallyl phthalate resin; a phenol resin; an epoxy resin; a silicone resin; a polysulfone resin; and a urea resin. One kind of binder resin may be used alone, or two or more kinds thereof may be mixed and used as a copolymer. Further, an additive such as a known plasticizer, antioxidant, or ultraviolet absorber may be used in combination as required.

An anode material preferably has as large a work function as possible, and examples thereof include: a metal element such as gold, platinum, silver, copper, nickel, palladium, cobalt, selenium, vanadium, or tungsten; an alloy thereof; and a metal oxide such as tin oxide, zinc oxide, indium oxide, indium tin oxide (ITO), or indium zinc oxide. Further, a conductive polymer such as polyaniline, polypyrrole, polythiophene, or polyphenylene sulfide may also be used. Each of those electrode materials may be used alone, or two or more kinds thereof may be used in combination. Further, the anode may have a single layer structure or a multilayer structure.

Meanwhile, a cathode material preferably has a small work function, and examples thereof include: a metal element such as lithium, sodium, potassium, calcium, magnesium, aluminum, indium, ruthenium, titanium, manganese, yttrium, silver, lead, tin, or chromium; and an alloy thereof such as a lithium-indium alloy, a sodium-potassium alloy, a magnesium-silver alloy, an aluminum-lithium alloy, an aluminum-magnesium alloy, or a magnesium-indium alloy. A metal oxide such as indium tin oxide (ITO) may also be used. Each of those electrode materials may be used alone, or two or more kinds thereof may be used in combination. Further, the cathode may have a single layer structure or a multilayer structure.

At least either one of the anode and the cathode is preferably transparent or semitransparent.

The substrate to be used in the present invention is not particularly limited, but examples thereof include: an opaque substrate such as a metallic substrate or a ceramics substrate; and a transparent substrate such as a glass substrate, a quartz substrate, or a plastic sheet substrate. In addition, the substrate may have a color filter film, a fluorescent color converting filter film, a dielectric reflection film, or the like for controlling luminescent color.

Further, a protective layer or a sealing layer may be formed on the produced device to prevent contact between the device and oxygen, moisture, or the like. Examples of the protective layer include: a diamond thin film; a film formed of an inorganic material such as metal oxide or metal nitride; a polymer film formed of a fluorine resin, polyparaxylene, polyethylene, a silicone resin, or a polystyrene resin; and a photo-curable resin. Further, the device itself may be covered with glass, an airtight film, a metal, or the like and packaged with an appropriate sealing resin.

### EXAMPLES

Hereinafter, the present invention will be described more specifically with reference to examples, but the present invention is not limited to the examples.

First, the structural formulae of the organic radical compounds used in Examples of the present invention will be shown below.

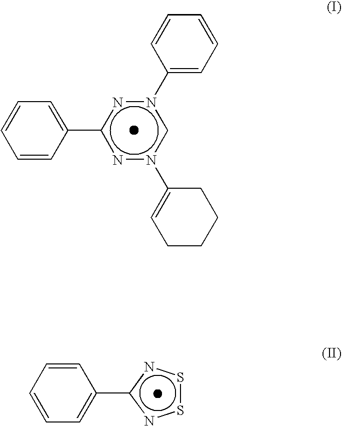

### Synthesis Example 1

### (Method of Synthesizing Compound (I))

Used as a compound (I) was a conventionally well known verdazyl radical, and synthesizing thereof was performed according to a synthesizing method described in Organic letters, 6 (12), 1887 (2004) or Japanese Patent Application Laid-Open No. H08-306516. HOMO (Ip: ionization potential) of the compound (I) was determined to be 5.5 eV using a photoelectron spectroscopy apparatus AC-1 (manufactured Riken Keiki Co., Ltd.), and LUMO was calculated to be 2.1 eV from the optical band gap obtained from the absorption spectrum.

### Synthesis Example 2

(Method of Synthesizing Compound (II))

Used as a compound (II) was a conventionally well known dithiaziazolyl radical, and synthesizing thereof was performed according to a synthesizing method described in Studies In Inorganic Chemistry, 14, 323 (1992) or Jouranal of the AmericanChemical Society, 113 (2), 582 (1991). HOMO (Ip: ionization potential) of the compound (II) was determined to be 5.6 eV using a photoelectron spectroscopy apparatus AC-1 (manufactured by Riken Keiki Co., Ltd.), and LUMO was calculated to be 2.2 eV from the optical band gap obtained from the absorption spectrum.

### Example 1

An organic light emitting device having the structure illustrated in FIG. 3 was manufactured by the method described below.

Indium tin oxide (ITO) as the anode 2 was formed as a film having a thickness of 120 nm on a glass substrate as the substrate 1 by a sputtering method, and the resultant was used as a transparent electrical conductive supporting substrate. The resultant substrate was subjected to ultrasonic cleaning in acetone and isopropyl alcohol (IPA) in the stated order. Then, the substrate was washed in boiling IPA and dried. The substrate was further subjected to UV/ozone cleaning to be used as a transparent electrical conductive supporting substrate.

The compound (I) as the organic radical compound and a hole transporting material (NPD) represented by the following structural formula were weighed in such a manner as to contain 10 wt % of the compound (I), and a chloroform solution was prepared in such a manner that the concentration of the mixture was 0.5 wt %.

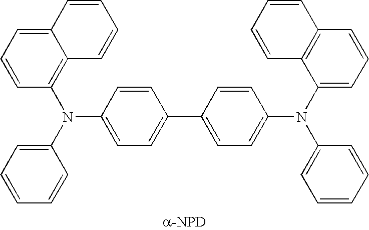

This solution was dropped onto the above-mentioned ITO electrode and formed into a film on the ITO electrode through spin coating at a revolving speed of 500 rpm for 10 seconds at first and then at a revolving speed of 1,000 rpm for 1 minute. Then, the whole was placed in a vacuum oven at 80° C. and dried for 10 minutes, to thereby completely remove the solvent in the thin film. The thus-formed hole injecting and transporting layer 3 had a thickness of 50 nm.

Next, aluminium quinolinol complex (Alq₃) was vapor deposited on the hole injecting and transporting layer, to form a light emitting layer 8 having a thickness of 20 nm. A degree of vacuum during deposition was 1.0×10⁻⁴ Pa and a film formation rate was 0.2 to 0.3 nm/second.

Further, as an electron transporting layer 9, bathophenanthroline (BPhen) was formed into a film having a thickness of 40 nm through a vacuum deposition method. A degree of vacuum during deposition was 1.0×10⁻⁴ Pa and a film formation rate was 0.2 to 0.3 nm/second.

Next, a vapor deposition material including aluminium-lithium alloy (lithium concentration: 1 atom %) was formed into a metal film layer having a thickness of 10 nm on the organic layer by a vacuum deposition method, and an aluminum film having a thickness of 150 nm was formed thereon through a vacuum deposition method, to thereby produce an organic light emitting device containing the aluminium-lithium alloy as the electron injecting electrode (cathode 5). A degree of vacuum during deposition was 1.0×10⁻⁴ Pa and a film formation rate was 1.0 to 1.2 nm/second.

The obtained organic light emitting device was covered with a protective glass and sealed with an acrylic resin binder in a dry air atmosphere to prevent degradation of the device by adsorption of moisture thereon.

Under application of a voltage of 4 V to the thus-obtained organic light emitting device having the ITO electrode (anode 2) as a positive electrode and the Al—Li electrode (cathode 5) as a negative electrode, green light emission with an emission luminance of 500 cd/m² and a light emitting efficiency of 4.5 lm/W was observed.

Further, the initial luminance of the device was adjusted to 200 cd/m², and the device was subjected to a durability test for 100 hours under a nitrogen atmosphere. Thus, the luminance after the durability test was 192 cd/m² (luminance retention {(192/200)×100=96 (%)}), which indicated that 90% or more of the initial luminance was retained, resulting in slight luminance degradation.

### Example 2

The same procedure as in Example 1 was followed except using a compound (II) in place of the organic radical compound (I), thereby manufacturing a device.

Under application of a voltage of 4.1 V to the thus-obtained organic light emitting device having the ITO electrode (anode 2) as a positive electrode and the Al—Li electrode (cathode 5) as a negative electrode, green light emission with an emission luminance of 500 cd/m² and a light emitting efficiency of 4.7 lm/W was observed.

Further, the initial luminance of the device was adjusted to 200 cd/m², and the device was subjected to a durability test for 100 hours under a nitrogen atmosphere. Thus, the luminance after the durability test was 188 cd/m² (luminance retention {(188/200)×100=94 (%)}), which indicated that 90% or more of the initial luminance was retained, resulting in slight luminance degradation.

### Comparative Example 1

The same procedure as in Example 1 was followed except not using the organic radical compound (I), thereby manufacturing a device, and the same evaluation was performed. Under application of a voltage of 6.9 V to the thus-obtained organic light emitting device, green light emission with an emission luminance of 500 cd/m² and a light emitting efficiency of 2.4 lm/W was observed.

Further, the initial luminance of the device was adjusted to 200 cd/m², and the device was subjected to a durability test for 100 hours under a nitrogen atmosphere. As a result, the luminance after the durability test was 162 cd/m² (luminance retention {(162/200)×100=81 (%)}), which indicated that about 80% of the initial luminance was retained.

The present invention can be applied to a practicable organic light emitting device which has a layer containing an organic radical compound, exhibits optical output with high light emitting efficiency and high luminance at low applied voltages, and also has excellent durability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-326054, filed Dec. 1, 2006, which is hereby incorporated by reference herein in its entirety.

What is claimed is:

1. An organic light emitting device comprising:
a pair of electrodes formed of an anode and a cathode,
at least one of which is transparent or semitransparent; and
an organic layer interposed between the pair of electrodes, wherein the organic layer contains an organic radical compound represented by the following general formula (1) or (2): 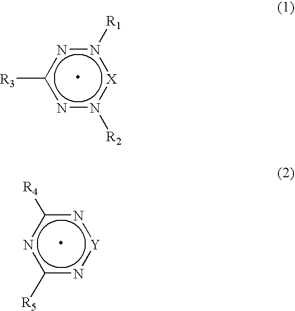
wherein X represents a carbon atom, —(C═O)—, or —(C═S)—; Y represents an oxygen atom or a sulfur atom; and R₁ to R₅ each independently represent a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

2. An organic light emitting device comprising:
a pair of electrodes formed of an anode and a cathode,
at least one of which is transparent or semitransparent; and
an organic layer interposed between the pair of electrodes, wherein the organic layer contains an organic radical compound represented by the following general formula (3): 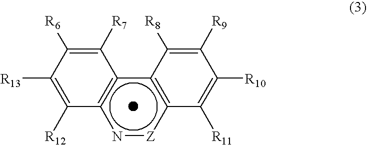
wherein Z represents an oxygen atom or a sulfur atom; and R₆ to R₁₃ each independently represent a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

3. An organic light emitting device comprising:
a pair of electrodes formed of an anode and a cathode,
at least one of which is transparent or
semitransparent; and
an organic layer interposed between the pair of electrodes, wherein the organic layer contains an organic radical compound represented by the following general formula (4): 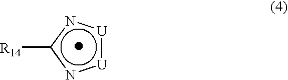
wherein U represents an oxygen atom or a sulfur atom;
and R₁₄ represents a hydrogen atom, a deuterium atom, halogen, an alkyl group, an alkenyl group, an aralkyl group, an alkynyl group, a substituted or unsubstituted aromatic group, or a substituted or unsubstituted heterocyclic group.

4. An organic light emitting device comprising, in an organic layer, an organic radical compound having units each represented by any one of the general formulae (1) to (4) of claims 1 to 3 wherein the units are directly bonded or bonded via a bivalent or trivalent aromatic ring, heterocyclic ring, or aromatic amine.

5. An organic light emitting device comprising, in an organic layer, an organic radical compound having units each represented by the general formula (1) or (2) of claim 1 wherein the units are directly bonded or bonded via a bivalent or trivalent aromatic ring, heterocyclic ring, or aromatic amine.

6. An organic light emitting device comprising, in an organic layer, an organic radical compound having units each represented by the general formula (3) of claims 2 wherein the units are directly bonded or bonded via a bivalent or trivalent aromatic ring, heterocyclic ring, or aromatic amine.

7. An organic light emitting device comprising, in an organic layer, an organic radical compound having units each represented by the general formula (4) of claims 3 wherein the units are directly bonded or bonded via a bivalent or trivalent aromatic ring, heterocyclic ring, or aromatic amine.

8. An organic light emitting device comprising, in an organic layer, an oligomer or a polymer having the units each represented by the general formula (1) or (2) of claim 1 as a partial structure.

9. An organic light emitting device comprising, in an organic layer, an oligomer or a polymer having the units each represented by the general formula (3) of claim 2 as a partial structure.

10. An organic light emitting device comprising, in an organic layer, an oligomer or a polymer having the units each represented by the general formula (4) of claim 3 as a partial structure.

11. The organic light emitting device according to claim 1, which is manufactured by forming a film using a mixture of an organic substance containing an organic radical compound and a solvent.

12. The organic light emitting device according to claim 2, which is manufactured by forming a film using a mixture of an organic substance containing an organic radical compound and a solvent.

13. The organic light emitting device according to claim 3, which is manufactured by forming a film using a mixture of an organic substance containing an organic radical compound and a solvent.

14. The organic light emitting device according to claim 1, wherein the organic layer is a hole injecting layer or a hole transporting layer.

15. The organic light emitting device according to claim 2, wherein the organic layer is a hole injecting layer or a hole transporting layer.

16. The organic light emitting device according to claim 3, wherein the organic layer is a hole injecting layer or a hole transporting layer.
